(19) United States
(12) Patent Application Publication
(10) Pub. No.: US 2026/0020276 A1
(43) Pub. Date: Jan. 15, 2026

(54) SEMICONDUCTOR DEVICE AND MANUFACTURING METHOD THEREOF

(71) Applicant: Nuvoton Technology Corporation Japan, Kyoto (JP)

(72) Inventors: Katsuhiko KAWASHIMA, Hyogo (JP); Yusuke KANDA, Toyama (JP); Tatsuya KOBAYASHI, Toyama (JP); Tatsuya YAGI, Toyama (JP)

(21) Appl. No.: 19/330,703

(22) Filed: Sep. 16, 2025

Related U.S. Application Data
(63) Continuation of application No. PCT/JP2024/011682, filed on Mar. 25, 2024.
(60) Provisional application No. 63/493,199, filed on Mar. 30, 2023.

(51) Int. Cl. H10D 30/47; H01L 23/29; H01L 23/31; H10D 30/01; H10D 64/00; H10D 64/27

(52) U.S. Cl. CPC H10D 30/475; H01L 23/291; H01L 23/3171; H01L 23/3192; H10D 30/015; H10D 64/111; H10D 64/411

(57) ABSTRACT

A semiconductor device includes: a substrate; a channel layer; a nitride semiconductor layer that includes a barrier layer; a source electrode; a drain electrode; a gate electrode; and an insulating layer. The gate electrode includes a junction portion and a drain-side protruding portion. The insulating layer includes an in-situ Si₃N₄ film and an ex-situ Si₃N₄ film. At least one of the following is satisfied: (a) the halogen concentration of the in-situ Si₃N₄ film is lower than the halogen concentration of the ex-situ Si₃N₄ film; or (b) the interface oxygen concentration between the in-situ Si₃N₄ film and the nitride semiconductor layer is lower than the interface oxygen concentration between the ex-situ Si₃N₄ film and the in-situ Si₃N₄ film.

### CROSS REFERENCE TO RELATED APPLICATIONS

This is a continuation application of PCT International Application No. PCT/JP2024/011682 filed on Mar. 25, 2024, designating the United States of America, which is based on and claims priority of U.S. Provisional Patent Application No. 63/493,199 filed on Mar. 30, 2023. The entire disclosures of the above-identified applications, including the specifications, drawings, and claims are incorporated herein by reference in their entirety.

### FIELD

The present disclosure relates to a semiconductor device and a manufacturing method thereof.

### BACKGROUND

In recent years, development of GaN High Electron Mobility Transistors (HEMTs) used for power amplifiers for high-frequency wireless communication has been advancing. GaN HEMTs have the following three main characteristics in terms of physical properties.

More specifically, these are: an electron carrier transport mechanism utilizing the high mobility of two-dimensional electron gas (hereinafter referred to as 2DEG); high withstand voltage due to the wide bandgap properties of the semiconductor; and high current driving capability due to high piezoelectric effect. Due to these characteristics, GaN HEMTs are optimal devices for applications that satisfy both high-speed and high-output characteristics, and their application to high-frequency wireless base stations, high-speed charging, and the like has been advancing.

As described above, GaN HEMTs are characterized by their ability to achieve high saturation current due to the piezoelectric effect. To maximize performance, it is effective to form a silicon nitride film (Si₃N₄ film) with strong piezo stress as a protective film on the GaN epitaxial substrate. Generally, Si₃N₄ films with dense film quality tend to have strong piezo stress. However, in the Si₃N₄ film that serves as a protective film for the epitaxial substrate, current collapse phenomenon occurs due to impurity levels characteristic of GaN HEMTs, so the Si₃N₄ film is also required to be a Si₃N₄ film with few impurity levels at the interface with the epitaxial surface.

Here, the current collapse phenomenon will be briefly explained. First, the phenomenon begins when hot electron carriers generated during high-voltage operation are trapped by impurity levels formed at the interface between the epitaxially grown semiconductor surface and the Si₃N₄ film, resulting in negative charging. Next, for electrons traveling through the 2DEG, this negative fixed charge is visible at a location in close proximity to the channel through which they travel, causing this fixed charge to become a scattering factor for the traveling electrons. As a result, this phenomenon, in which the saturation velocity deteriorates and the on-resistance characteristics degrade, is the current collapse phenomenon.

A method exists for utilizing a Si₃N₄ film that satisfies the conditions of being dense and having few interface states by continuously growing the Si₃N₄ film in the same growth furnace used for the epitaxial substrate. Generally, this Si₃N₄ film is referred to as an in-situ Si₃N₄ film. A Si₃N₄ film is deposited on the GaN epitaxial layer to compensate for nitrogen deficiencies on the surface during the process steps. In the case of the in-situ Si₃N₄ film, because Si₃N₄ is epitaxially grown during the epitaxial growth process, the epitaxial surface is not exposed to air, resulting in fewer nitrogen deficiencies. Therefore, because the in-situ Si₃N₄ film has the characteristic of fewer impurity levels caused by nitrogen deficiencies compared to conventional Si₃N₄ films, surface traps can be reduced. The technique of applying an in-situ Si₃N₄ film to GaN HEMTs is disclosed in NPL 1 and 2.

### CITATION LIST

### Non Patent Literature

NPL 1: J. Derluyn et al., “Low Leakage High Breakdown E-Mode DHFET on Si by Selective Removal of In-situ Grown Si₃N₄”, IEEE, 2009, IEDM09, pp. 157-160
NPL 2: F. Medjdoub et al., “Low On-Resistance High-Breakdown Normally Off AlN/GaN/AlGaN DHFET on Si Substrate”, IEEE Electron Device Letters, February 2010, Vol. 31, No. 2, pp. 111-113

### SUMMARY

### Technical Problem

However, while utilizing an in-situ Si₃N₄ film provides advantages such as higher saturation current and improved collapse characteristics, it simultaneously introduces the following disadvantages as trade-offs. Specifically, there is a mechanical problem in which the wafer bows due to the strong piezo stress of the in-situ Si₃N₄ film.

In view of the above, the present disclosure provides a semiconductor device having both high drive current characteristics and low wafer bow characteristics and a manufacturing method thereof.

### Solution to Problem

A semiconductor device according to one aspect of the present disclosure includes: a substrate; a channel layer disposed above the substrate and including a nitride semiconductor containing gallium; a nitride semiconductor layer disposed above the channel layer and including a barrier layer containing gallium with a bandgap larger than a bandgap of the channel layer; a source electrode and a drain electrode disposed above the substrate and spaced apart from each other; a gate electrode disposed above the barrier layer and between the source electrode and the drain electrode, and spaced apart from each of the source electrode and the drain electrode; and an insulating layer disposed above the nitride semiconductor layer and between the gate electrode and the drain electrode. The gate electrode includes: a junction portion that forms a Schottky junction with the nitride semiconductor layer; and a first protruding portion that protrudes toward the drain electrode from the junction portion. The insulating layer includes: a first insulating film including silicon nitride, positioned between the first protruding portion and the nitride semiconductor layer, and contacting and covering the nitride semiconductor layer; and a second insulating film including silicon nitride and positioned between the first protruding portion and the first insulating film. The semiconductor device satisfies at least one of: (a) a halogen concentration of the first insulating film is lower than a halogen concentration of the second insulating film; or (b) an interface oxygen concentration between the first insulating film and the nitride semiconductor layer is lower than an interface oxygen concentration between the second insulating film and the first insulating film.

A manufacturing method of a semiconductor device according to one aspect of the present disclosure includes: a first process of sequentially forming, above a substrate by epitaxial growth, a channel layer including a nitride semiconductor containing gallium and a nitride semiconductor layer including a barrier layer containing gallium with a bandgap larger than a bandgap of the channel layer; a second process of forming an insulating layer to cover the nitride semiconductor layer; a third process of exposing a portion of the nitride semiconductor layer by removing a portion of the insulating layer; a fourth process of forming a source electrode and a drain electrode spaced apart from each other above the substrate; and a fifth process of forming a gate electrode between the source electrode and the drain electrode so as to be spaced apart from each of the source electrode and the drain electrode, the gate electrode being formed to contact an exposed portion of the nitride semiconductor layer and cover a portion of the insulating layer located toward the drain electrode relative to the exposed portion. The second process includes: after the first process, a process of forming a first insulating film including silicon nitride that contacts and covers the nitride semiconductor layer, without exposure to an atmosphere; and after forming the first insulating film, a process of forming a second insulating film including silicon nitride above the first insulating film, after exposure to the atmosphere.

### Advantageous Effects

According to the present disclosure, it is possible to provide a semiconductor device having both high drive current characteristics and low wafer bow characteristics and a manufacturing method thereof.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a semiconductor device according to Embodiment 1.

FIG. 2 illustrates the relationship between the thickness of a Si₃N₄ film and the carrier concentration of 2DEG.

FIG. 3 illustrates the relationship between the thickness of a Si₃N₄ film and wafer bow.

FIG. 4 is a cross-sectional view of a semiconductor device according to Embodiment 2.

FIG. 5 is a cross-sectional view of a semiconductor device according to Embodiment 3.

FIG. 6 is a cross-sectional view of a semiconductor device according to Embodiment 4.

FIG. 7 illustrates the current characteristics of a semiconductor device with respect to combinations of the thickness of an in-situ Si₃N₄ film and the thickness of a barrier layer.

FIG. 8 is a cross-sectional view of a semiconductor device for supplementary explanation of the current characteristics illustrated in FIG. 7.

FIG. 9A is a cross-sectional view for explaining a process of a manufacturing method of the semiconductor device according to Embodiment 3.

FIG. 9B is a cross-sectional view for explaining a process of a manufacturing method of the semiconductor device according to Embodiment 3.

FIG. 9C is a cross-sectional view for explaining a process of a manufacturing method of the semiconductor device according to Embodiment 3.

FIG. 9D is a cross-sectional view for explaining a process of a manufacturing method of the semiconductor device according to Embodiment 3.

FIG. 9E is a cross-sectional view for explaining a process of a manufacturing method of the semiconductor device according to Embodiment 3.

FIG. 9F is a cross-sectional view for explaining a process of a manufacturing method of the semiconductor device according to Embodiment 3.

FIG. 9G is a cross-sectional view for explaining a process of a manufacturing method of the semiconductor device according to Embodiment 3.

FIG. 9H is a cross-sectional view for explaining a process of a manufacturing method of the semiconductor device according to Embodiment 3.

FIG. 9I is a cross-sectional view for explaining a process of a manufacturing method of the semiconductor device according to Embodiment 3.

FIG. 9J is a cross-sectional view for explaining a process of a manufacturing method of the semiconductor device according to Embodiment 3.

FIG. 9K is a cross-sectional view for explaining a process of a manufacturing method of the semiconductor device according to Embodiment 3.

FIG. 10A is a cross-sectional view for explaining a process of a manufacturing method of the semiconductor device according to Embodiment 4.

FIG. 10B is a cross-sectional view for illustrating a process of a manufacturing method of the semiconductor device according to Embodiment 4.

FIG. 10C is a cross-sectional view for explaining a process of a manufacturing method of the semiconductor device according to Embodiment 4.

### DESCRIPTION OF EMBODIMENTS

### Overview of Present Disclosure

Hereinafter, embodiments will be described in detail with reference to the drawings.

Each of the embodiments described below shows a general or specific example. The numerical values, shapes, materials, elements, the arrangement and connection of the elements, steps, the processing order of the steps etc., described in the following embodiments are mere examples, and therefore do not limit the scope of the present disclosure. Among elements in the embodiments described below, those not recited in the independent claims are described as optional elements.

The drawings are schematically illustrated diagrams and do not necessarily give strict illustration. Therefore, for example, the scale and the like in the drawing do not necessarily match. Throughout the drawings, the same reference signs are given to elements that are substantially the same, and redundant description will be omitted or simplified.

In the present specification, terms indicating relationships between elements, such as parallel or perpendicular, terms indicating the shapes of elements, such as quadrilateral, and value ranges do not have the meanings in the strict sense only, but also represent essentially equivalent meanings and value ranges, and include, for example, deviations of about a few percent.

In the present specification, the terms “above” and “below” do not refer to the vertically upward direction and vertically downward direction in terms of absolute spatial recognition, but are used as terms defined by relative positional relationships based on the stacking order in a stacked configuration. In addition, the terms “above” and “below” are used not only when an element is present between two other elements spaced apart from each other, but also when two elements are disposed in close contact with each other.

In the present specification and drawings, the x-axis, the y-axis, and the z-axis refer to the three axes of a three-dimensional orthogonal coordinate system. Specifically, the x-axis and the y-axis are the two axes parallel to the main surface (top surface) included in a substrate that the semiconductor device includes, and the direction perpendicular to this main surface is a z-axis direction. More specifically, the direction in which the source electrode, the gate electrode, and the drain electrode are aligned in stated order; that is, the so-called gate length direction is referred to as the x-axis direction. In the embodiments described below, there are instances where the z-axis positive direction is described as “above” and the z-axis negative direction is described as “below”. In the present specification, unless otherwise specified, the source electrode side or the source side each means the negative side (negative direction) of the x-axis, and the drain electrode side or the drain side each means the positive side (positive direction) of the x-axis. In addition, in the present specification, “plan view” refers to the view of the main surface (top surface) of the substrate included in the semiconductor device from the z-axis positive direction, unless otherwise specified.

In addition, in the present specification, a group III nitride semiconductor is a semiconductor that contains one or more types of group III elements and nitrogen. Group III elements are, for example, aluminum (Al), gallium (Ga), indium (In), etc. GaN, AlN, InN, AlGaN, InGaN, and AlInGaN are included as examples of the group III nitride semiconductor. Group III nitride semiconductors may contain one or more types of elements other than Group III, such as silicon (Si) and phosphorus (P). It should be noted that, in the following description, when described as AlInGaN without any particular explanation, it means that the group III nitride semiconductor contains each of Al, In, Ga, and N. The same applies to other descriptions such as AlGaN and GaN.

A layer consisting of material A such as a group III nitride semiconductor like GaN or AlGaN, silicon nitride, or silicon oxide, and a layer composed of material A each mean that the layer contains substantially only material A. However, the above-described layer may contain other elements, as impurities, such as elements that cannot be avoided in the manufacturing process, at a ratio of 1 at % or less.

In addition, in the present specification, the composition ratio of the group III element of a nitride semiconductor (layer) represents the ratio of a total number of atoms of the target group III element among a plurality of group III elements included in the nitride semiconductor. For example, when a nitride semiconductor layer consists of AlₐIn_{b}Ga_{c}N (a+b+c=1, a≥0, b≥0, c≥0), the Al composition ratio of the nitride semiconductor layer can be expressed as a/(a+b+c). In the same manner, the In composition ratio and the Ga composition ratio are expressed as b/(a+b+c) and c/(a+b+c), respectively.

In addition, in the present specification, ordinal numerals such as “first” and “second” do not mean a total number or an order of elements, unless otherwise noted, but are used to avoid confusion and distinguish between elements of the same type.

### Embodiment 1

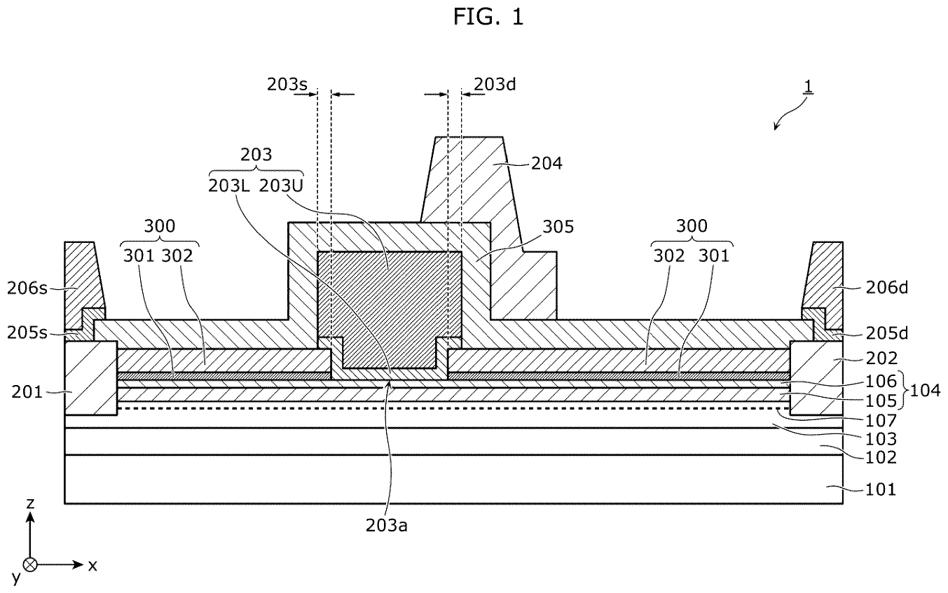

First, a semiconductor device according to Embodiment 1 will be described with reference to FIG. 1. FIG. 1 is a cross-sectional view of semiconductor device 1 according to the present embodiment.

As illustrated in FIG. 1, semiconductor device 1 includes substrate 101, buffer layer 102, channel layer 103, and nitride semiconductor layer 104. Nitride semiconductor layer 104 includes barrier layer 105 and cap layer 106. 2DEG 107 is formed in proximity to the interface between channel layer 103 and barrier layer 105. Buffer layer 102, channel layer 103, barrier layer 105 and cap layer 106 are epitaxial layers (also called epi layers) formed by epitaxial growth. Semiconductor device 1 includes source electrode 201, drain electrode 202, gate electrode 203, source field plate 204, barrier metals 205s and 205d, and wiring metals 206s and 206d.

Semiconductor device 1 includes insulating layers 300 and 305. Insulating layer 300 includes in-situ Si₃N₄ film 301 and ex-situ Si₃N₄ film 302.

Substrate 101 is a substrate consisting of Si. Alternatively, substrate 101 may be a Silicon on Insulator (SOI) substrate. Substrate 101 may also be a substrate consisting of SiC, sapphire, diamond, GaN, or AlN, or the like.

Buffer layer 102 is disposed above substrate 101. For example, buffer layer 102 is disposed in contact with the top surface of substrate 101. Buffer layer 102 is, for example, a layer consisting of a group III nitride semiconductor. As an example, buffer layer 102 has a stacked structure consisting of a plurality of layers of AlN and AlGaN, and has a thickness of 2 μm. Buffer layer 102 may otherwise be composed of a single layer or a plurality of layers of group III nitride semiconductors such as GaN, AlGaN, AlN, InGaN, AlInGaN, etc.

Providing buffer layer 102 makes it possible to reduce adverse effects such as crystal dislocation and lattice defects resulting from the difference in lattice spacing between substrate 101 and channel layer 103. Even if there are defects in substrate 101, providing buffer layer 102 makes it possible to inhibit the influence these defects have on channel layer 103. With this configuration, it is possible to reduce defects in channel layer 103, enhance crystallinity, and increase electron mobility in channel layer 103. Note that buffer layer 102 need not necessarily be provided.

Channel layer 103 is disposed above substrate 101. Specifically, channel layer 103 is disposed in contact with the top surface of buffer layer 102. Channel layer 103 is a layer consisting of a nitride semiconductor containing gallium. For example, channel layer 103 is composed of GaN. The thickness of channel layer 103 is, for example, greater than or equal to 50 nm and less than or equal to 300 nm, and in one example is 200 nm. It should be noted that channel layer 103 is not limited to GaN, but may be composed of a group III nitride semiconductor such as InGaN, AlGaN, AlInGaN, etc. In addition, channel layer 103 may contain an n-type impurity. The thickness of channel layer 103 is not limited to the example described above.

Barrier layer 105 is disposed above channel layer 103. Specifically, barrier layer 105 is disposed in contact with the top surface of channel layer 103. Note that a spacer layer consisting of AlN with a thickness of approximately 1 nm may be disposed between barrier layer 105 and channel layer 103. As described above, channel layer 103 and barrier layer 105 need not necessarily be in contact with each other.

Barrier layer 105 is a layer consisting of a nitride semiconductor containing gallium with a larger bandgap than channel layer 103. Barrier layer 105 is composed of, for example, AlGaN. The Al composition ratio of barrier layer 105 is, for example, greater than or equal to 10% and less than or equal to 30%, but may be greater than or equal to 20% and less than or equal to 30%. The Al composition ratio of barrier layer 105 is, in one example, less than or equal to 25%. The thickness of barrier layer 105 is greater than or equal to 7 nm and less than or equal to 10 nm, and in one example is 9 nm. Note that the thickness of barrier layer 105 may be less than or equal to 15 nm, may be less than or equal to 20 nm, and may be less than or equal to 30 nm. In addition, barrier layer 105 is not limited to AlGaN, but may be composed of a group III nitride semiconductor such as AlInGaN, etc. In addition, barrier layer 105 may contain an n-type impurity.

By barrier layer 105 containing gallium, the lattice spacing of barrier layer 105 is more easily relaxed compared to when it is composed of AlN that does not contain gallium. For this reason, it is possible to inhibit the occurrence of cracks, etc., in barrier layer 105. It is also possible to inhibit bowing of the wafer. Therefore, the quality of semiconductor device 1 can be improved.

A high-concentration 2DEG 107 is generated on the channel layer 103 side of the hetero interface between barrier layer 105 and channel layer 103 due to piezo stress, etc., of barrier layer 105 with respect to channel layer 103. 2DEG 107 is used as a channel for the transistor.

Cap layer 106 contacts and covers the top surface of barrier layer 105. Cap layer 106 is a layer consisting of a group III nitride semiconductor. Cap layer 106 is composed of, for example, GaN. The thickness of cap layer 106 is, for example, greater than or equal to approximately 1 nm and less than or equal to approximately 2 nm. Providing cap layer 106 makes it possible to inhibit oxidation of Al in barrier layer 105. Cap layer 106 need not necessarily be provided.

Source electrode 201 and drain electrode 202 are disposed apart from each other, above substrate 101. More specifically, source electrode 201 and drain electrode 202 are disposed facing each other with gate electrode 203 interposed therebetween.

Source electrode 201 and drain electrode 202 are formed using conductive materials. For example, source electrode 201 and drain electrode 202 are multilayer electrode films having a stacked structure in which a Ti film and an Al film are stacked in sequence, but not limited to this example. Source electrode 201 and drain electrode 202 may be an alloy layer formed by annealing the stacked structure of a Ti film and an Al film at a temperature of 500° C. or higher. Source electrode 201 and drain electrode 202 may be a transition metal, or a nitride or carbide of transition metal. More specifically, source electrode 201 and drain electrode 202 may be Ta, Hf, W, Ni, TiN, TaN, HAN, WN, TiC, TaC, HfC, Au, Cu, etc., a compound containing these elements, or a multilayer electrode film having a plurality of stacked structures.

Source electrode 201 and drain electrode 202 are each also called ohmic electrodes, and are each electrically in ohmic contact with 2DEG 107. In the present embodiment, source electrode 201 and drain electrode 202 are each disposed so as to be in contact with 2DEG 107.

More specifically, in semiconductor device 1, two recesses are provided that penetrate through cap layer 106 and barrier layer 105 to reach channel layer 103. The two recesses are also referred to as a source opening portion and a drain opening portion. Source electrode 201 is disposed so as to be in contact with and cover the inner surface of the source opening portion, and drain electrode 202 is disposed so as to be in contact with and cover the inner surface of the drain opening portion. The bottom surface of each of the two recesses is located below the interface between channel layer 103 and barrier layer 105. Accordingly, 2DEG 107 is exposed on the side surface of each of the two recesses. Source electrode 201 and drain electrode 202 are in contact with 2DEG 107 on the side surfaces of the recesses. This configuration makes it possible to reduce the channel contact resistance. Note that instead of the recesses, a source contact region and a drain contact region with reduced resistance may be provided by adding n-type impurities to portions of cap layer 106, barrier layer 105, and channel layer 103. The source contact region and the drain contact region are formed by, for example, plasma treatment, ion implantation, and crystal regrowth.

Source electrode 201 and drain electrode 202 are each covered with an insulating film (specifically, insulating layer 305 before openings are formed) during the manufacturing process of semiconductor device 1. In order to ensure contact to source electrode 201 and drain electrode 202, openings are provided in insulating layer 305, and wiring metals 206s and 206d are connected to source electrode 201 and drain electrode 202, respectively, through the openings. Wiring metals 206s and 206d are formed using, for example, low-resistance Au.

When wiring metal 206s containing Au comes into contact with source electrode 201 containing Al, a reaction between the materials may occur under high-temperature environments. To avoid this reaction, barrier metal 205s is disposed between source electrode 201 and wiring metal 206s. Similarly, barrier metal 205d is disposed between drain electrode 202 and wiring metal 206d. Barrier metals 205d and 205s are formed using a material containing metal with a high melting point that is unlikely to react even at high temperatures. For example, barrier metals 205d and 205s are TiN films. It should be noted that barrier metals 205d and 205s, as well as wiring metals 206d and 206s, need not necessarily be provided. For example, source electrode 201 and drain electrode 202 may additionally serve as wiring.

Gate electrode 203 is disposed above barrier layer 105, between source electrode 201 and drain electrode 202 so as to be spaced apart from each of source electrode 201 and drain electrode 202. In the present embodiment, gate electrode 203 has a multilayer structure including gate electrode lower portion 203L and gate electrode upper portion 203U.

Gate electrode lower portion 203L is formed using a conductive material that can form a Schottky junction with a nitride semiconductor containing gallium. For example, gate electrode lower portion 203L is formed using Ni, Ti, TiN, TaN, W, Pd, or the like. Gate electrode lower portion 203L is positioned as the lowermost layer of the multilayer structure of gate electrode 203, and is in contact with cap layer 106 and insulating layer 300. The thickness of gate electrode lower portion 203L is, for example, greater than or equal to 10 nm and less than or equal to 50 nm, and in one example is 50 nm, but is not limited thereto.

Gate electrode upper portion 203U is formed using a material having a lower resistivity than gate electrode lower portion 203L. For example, gate electrode upper portion 203U is formed using Au or Al, or the like. Gate electrode upper portion 203U is disposed so as to be in contact with and cover the top surface of gate electrode lower portion 203L. The thickness of gate electrode upper portion 203U is, for example, greater than or equal to 450 nm and less than or equal to 650 nm, and in one example is 500 nm, but is not limited thereto. In plan view, the shape and size of gate electrode upper portion 203U are substantially the same as the shape and size of gate electrode lower portion 203L.

Giving gate electrode 203 a multilayer structure in this manner makes it possible to reduce gate resistance Rg in the y-axis direction while ensuring the Schottky junction. Reducing gate resistance Rg makes it possible to improve high-frequency gain. Note that gate electrode 203 need not have a multilayer structure, and may have a single-layer structure formed using a conductive material that can form a Schottky junction with a nitride semiconductor containing gallium.

Gate electrode 203 has a so-called T-type gate structure. More specifically, gate electrode 203 includes junction portion 203a, drain-side protruding portion 203d, and source-side protruding portion 203s. Drain-side protruding portion 203d and source-side protruding portion 203s are also referred to as gate field plates.

Junction portion 203a forms a Schottky junction with nitride semiconductor layer 104. More specifically, junction portion 203a is the portion of the bottom surface of gate electrode lower portion 203L that is in contact with cap layer 106. Note that in configurations in which cap layer 106 is not provided, junction portion 203a is the portion of the bottom surface of gate electrode lower portion 203L that is in contact with barrier layer 105.

Drain-side protruding portion 203d is one example of the first protruding portion, and is a portion that protrudes toward the drain electrode 202 side from junction portion 203a. Drain-side protruding portion 203d corresponds to one arm of the T-shape in the T-type gate structure.

Source-side protruding portion 203s is one example of the second protruding portion, and is a portion that protrudes toward the source electrode 201 side from junction portion 203a. Source-side protruding portion 203s corresponds to one arm of the T-shape in the T-type gate structure.

In the present embodiment, the protrusion length of drain-side protruding portion 203d and the protrusion length of source-side protruding portion 203s are the same. More specifically, the cross-sectional shape of gate electrode 203 in the xz cross-section is symmetrical about a line that runs parallel to the z-axis passing through the center of junction portion 203a.

It should be noted that the protrusion length of the protruding portion refers to the distance along the x-axis direction from the starting point to the tip of the protruding portion. The starting point of the protruding portion can be considered as the outline of junction portion 203a in plan view. The tip of the protruding portion is the position farthest from the starting point in the protrusion direction of the protruding portion. For drain-side protruding portion 203d, the protrusion direction is the positive direction of the x-axis, and for source-side protruding portion 203s, the protrusion direction is the negative direction of the x-axis.

Drain-side protruding portion 203d and source-side protruding portion 203s are each exemplified as, but not limited to, having a multilayer structure of gate electrode upper portion 203U and gate electrode lower portion 203L. For example, drain-side protruding portion 203d and source-side protruding portion 203s may each include only low-resistance gate electrode upper portion 203U. That is, gate electrode lower portion 203L may be provided only in the portion where gate electrode 203 and cap layer 106 (or barrier layer 105) are in contact with each other (i.e., the portion corresponding to junction portion 203a).

The distance along the x-axis from the drain-side end portion of junction portion 203a to drain electrode 202 is called gate-drain distance Lgd. The distance along the x-axis from the source-side end portion of junction portion 203a to source electrode 201 is called gate-source distance Lgs. In the present embodiment, Lgs<Lgd. For example, Lgd is 3.2 μm, and Lgs is 1.3 μm. By making gate-drain distance Lgd longer than gate-source distance Lgs, it is possible to relax the electric field concentration applied between the gate and drain. Note that satisfying Lgs<Lgd is not essential; Lgs may be equal to Lgd, or Lgs may be greater than Lgd.

Source field plate 204 is disposed above gate electrode 203 and set at the same electric potential as source electrode 201. More specifically, source field plate 204 is disposed above insulating layer 305. Source field plate 204 is disposed such that at least a portion thereof is positioned between gate electrode 203 and drain electrode 202 in a plan view. In the example illustrated in FIG. 1, source field plate 204 is placed such that a portion thereof overlaps gate electrode 203 in a plan view. Source field plate 204 is electrically insulated from gate electrode 203 and drain electrode 202, and is set at an electric potential (source electric potential) applied to source electrode 201.

During operation of semiconductor device 1, a high voltage of approximately 100 V to 150 V maximum is applied to drain electrode 202. At that time, a high electric field is applied between drain electrode 202 and gate electrode 203. More specifically, electric power lines from drain electrode 202 concentrate at the end portion of drain-side protruding portion 203d of gate electrode 203, causing the peak value of the electric field to increase and reliability to decrease. Providing source field plate 204 makes it possible to reduce the peak value of this electric field. Source field plate 204 can relax the high electric field peak by dispersing it in the x-axis direction. With this configuration, it is possible to improve the withstand voltage between the gate and drain, and improve the reliability by inhibiting the gate leakage current.

Source field plate 204 is formed using a conductive material. Source field plate 204 is, for example, a multilayer electrode film having a stacked structure in which a TiN film and an Al film are stacked in sequence. The thickness of source field plate 204 is, for example, 500 nm, but is not limited thereto. It should be noted that source field plate 204 is not limited to the stacked structure of a TIN film and an Al film, but may be a nitride or carbide of transition metal deposited by sputtering. More specifically, source field plate 204 may be Ti, Ta, W, Ni, TiN, TaN, WN, W, Au, Cu, etc., a compound containing these elements, or a multilayer electrode film having a plurality of stacked structures. In one example, source field plate 204 has a multilayer structure in which Ti, TiN, and Al are stacked in this order from the bottom layer. Alternatively, source field plate 204 may include Au in the uppermost layer.

Insulating layer 305 is disposed between gate electrode 203 and source field plate 204. More specifically, insulating layer 305 is disposed so as to cover the entire area of semiconductor device 1. Insulating layer 305 includes openings for securing contact to each of source electrode 201 and drain electrode 202.

Insulating layer 305 is composed of Si₃N₄ with a thickness of 110 nm, for example. It should be noted that insulating layer 305 is not limited to Si₃N₄, but may be SiO₂ or SiON. In addition, Si₃N₄ included in insulating layer 305 may be stress controlled by changing the Si composition ratio or the N composition ratio. It should be noted that insulating layer 305 and source field plate 204 need not necessarily be provided.

Insulating layer 300 is disposed above nitride semiconductor layer 104 and disposed between gate electrode 203 and drain electrode 202. More specifically, insulating layer 300 is disposed between gate electrode 203 and drain electrode 202, contacting and covering the top surface of cap layer 106. Insulating layer 300 is disposed over the entire area from the drain-side end portion of junction portion 203a to drain electrode 202.

In the present embodiment, insulating layer 300 is also disposed between gate electrode 203 and source electrode 201. More specifically, insulating layer 300 contacts and covers the top surface of cap layer 106, between gate electrode 203 and source electrode 201. Insulating layer 300 is disposed over the entire area from the source-side end portion of junction portion 203a to source electrode 201.

Insulating layer 300 has a stacked structure of a plurality of insulating layers. Specifically, insulating layer 300 includes in-situ Si₃N₄ film 301 and ex-situ Si₃N₄ film 302.

In-situ Si₃N₄ film 301 is an example of a first insulating film consisting of silicon nitride, positioned between drain-side protruding portion 203d and nitride semiconductor layer 104, and in contact with and covering nitride semiconductor layer 104. In-situ Si₃N₄ film 301 overlaps with drain-side protruding portion 203d in a plan view. In-situ Si₃N₄ film 301 is the lowermost layer in the stacked structure of insulating layer 300. In the present embodiment, in-situ Si₃N₄ film 301 is disposed between gate electrode 203 and drain electrode 202, contacting and covering cap layer 106 over the entire area from the drain-side end portion of junction portion 203a to drain electrode 202.

In the present embodiment, in-situ Si₃N₄ film 301 is also disposed between gate electrode 203 and source electrode 201. In-situ Si₃N₄ film 301 overlaps with source-side protruding portion 203s in a plan view. More specifically, in-situ Si₃N₄ film 301 is contacting and covering cap layer 106 over the entire area from the source-side end portion of junction portion 203a to source electrode 201.

Ex-situ Si₃N₄ film 302 is an example of a second insulating film consisting of silicon nitride that is positioned between drain-side protruding portion 203d and in-situ Si₃N₄ film 301. More specifically, ex-situ Si₃N₄ film 302 overlaps with drain-side protruding portion 203d in a plan view, and contacts the bottom surface of drain-side protruding portion 203d. Ex-situ Si₃N₄ film 302 is contacting and covering in-situ Si₃N₄ film 301 over the entire area from the drain-side end portion of junction portion 203a to drain electrode 202.

In the present embodiment, ex-situ Si₃N₄ film 302 is also disposed between gate electrode 203 and source electrode 201. More specifically, ex-situ Si₃N₄ film 302 overlaps with source-side protruding portion 203s in a plan view, and contacts the bottom surface of source-side protruding portion 203s. Ex-situ Si₃N₄ film 302 is contacting and covering in-situ Si₃N₄ film 301 over the entire area from the source-side end portion of junction portion 203a to source electrode 201.

The thickness of in-situ Si₃N₄ film 301 is, for example, greater than or equal to 15 nm, but may be greater than or equal to 20 nm. Also, the thickness of in-situ Si₃N₄ film 301 is less than or equal to 30 nm, but may be less than or equal to 25 nm. In the present embodiment, the thickness of in-situ Si₃N₄ film 301 is substantially uniform.

The thickness of ex-situ Si₃N₄ film 302 is, for example, greater than or equal to 30 nm and less than or equal to 60 nm. Also, for example, the thickness of ex-situ Si₃N₄ film 302 is greater than or equal to the thickness of in-situ Si₃N₄ film 301. In the present embodiment, the thickness of ex-situ Si₃N₄ film 302 is substantially uniform.

In-situ Si₃N₄ film 301 and ex-situ Si₃N₄ film 302 have different manufacturing methods. More specifically, in-situ Si₃N₄ film 301 is formed continuously after epitaxial growth of the nitride semiconductor, without exposure to the atmosphere. That is, in-situ Si₃N₄ film 301 is a film continuously stacked on the grown nitride semiconductor layer in the epitaxial growth furnace. The growth furnace is, for example, a Metal Organic Chemical Vapor Deposition (MOCVD) furnace.

In contrast, ex-situ Si₃N₄ film 302 is formed after the formation of in-situ Si₃N₄ film 301, after being removed from the epitaxial growth furnace and exposed to the atmosphere. Ex-situ Si₃N₄ film 302 is formed, for example, by Low-Pressure Chemical Vapor Deposition (LPCVD).

Due to differences in manufacturing methods, in-situ Si₃N₄ film 301 and ex-situ Si₃N₄ film 302 have mutually different film qualities. Specifically, in-situ Si₃N₄ film 301 is a denser film than ex-situ Si₃N₄ film 302. For example, the film density of in-situ Si₃N₄ film 301 is greater than the film density of ex-situ Si₃N₄ film 302.

Also, in-situ Si₃N₄ film 301 and ex-situ Si₃N₄ film 302 differ in at least one of halogen concentration or interface oxygen concentration. For example, in the present embodiment, at least one of the following is satisfied: (a) the halogen concentration of in-situ Si₃N₄ film 301 is lower than the halogen concentration of ex-situ Si₃N₄ film 302; or (b) the interface oxygen concentration between in-situ Si₃N₄ film 301 and nitride semiconductor layer 104 is lower than the interface oxygen concentration between in-situ Si₃N₄ film 301 and ex-situ Si₃N₄ film 302. More specifically, at least one of the following is satisfied: (c) the halogen concentration of in-situ Si₃N₄ film 301 is less than 1×10¹⁸ atom/cm³, and the halogen concentration of ex-situ Si₃N₄ film 302 is greater than 1×10¹⁸ atom/cm³; or (d) the interface oxygen concentration between in-situ Si₃N₄ film 301 and nitride semiconductor layer 104 is less than 1×10²⁰ atom/cm³, and the interface oxygen concentration between in-situ Si₃N₄ film 301 and ex-situ Si₃N₄ film 302 is greater than 1×10²⁰ atom/cm³.

Table 1 shows the halogen concentration and interface oxygen concentration of each of in-situ Si₃N₄ and ex-situ Si₃N₄. More specifically, it shows the results of composition analysis performed by Secondary Ion Mass Spectroscopy (SIMS) on the stacked structure of in-situ Si₃N₄ and ex-situ Si₃N₄. The halogen concentration is, more specifically, the chlorine (CI) concentration.

TABLE 1

| | In-situ Si₃N₄ | Ex-situ Si₃N₄ |
|---|---|---|
| Halogen | Less than 1 × 10¹⁸ | Greater than 1 × 10¹⁸ |
| concentration | atom/cm³ | atom/cm³ |
| Interface oxygen | Less than 1 × 10²⁰ | Greater than 1 × 10²⁰ |
| concentration | atom/cm³ | atom/cm³ |

As illustrated in Table 1, one characteristic of in-situ Si₃N₄ film 301 is that it has a low halogen concentration and a low interface oxygen concentration with the epitaxially grown semiconductor (cap layer 106 in the present embodiment). This is because it is a stacked film formed in the epitaxial growth furnace, and since there is no exposure to the atmosphere, halogens such as Cl₂ and oxygen contained in the air of the cleanroom process site are less likely to be incorporated after epitaxial growth. Cl₂ is used as a dry etching gas in the processing, and it unintentionally enters the atmosphere in trace amounts.

As a result, the effects obtained from in-situ Si₃N₄ film 301 with fewer impurities such as halogens or oxygen include reduced interface states with the semiconductor and reduced influence on 2DEG 107. These effects also lead to increased collapse resistance. In the present embodiment, by providing in-situ Si₃N₄ film 301 on nitride semiconductor layer 104, it is possible to achieve good collapse characteristics and obtain high drive current characteristics.

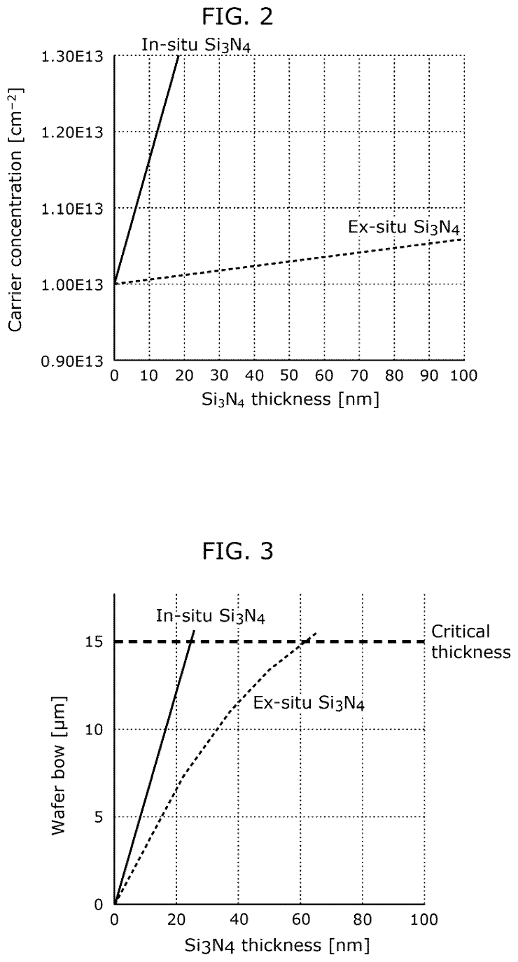

FIG. 2 illustrates the relationship between the thickness of the Si₃N₄ film and the carrier concentration of 2DEG 107. FIG. 2 illustrates a case where the in-situ Si₃N₄ film is formed on nitride semiconductor layer 104 (embodiment example) and a case where the ex-situ Si₃N₄ film is formed on nitride semiconductor layer 104 (comparative example). In FIG. 2, the horizontal axis represents the thickness of the Si₃N₄ film, and the vertical axis represents the carrier concentration of 2DEG 107 obtained by Hall measurement.

As illustrated in FIG. 2, since the in-situ Si₃N₄ film achieves a significantly higher carrier concentration than ex-situ Si₃N₄ film, the saturation current of the transistor increases. The higher the saturation current, the higher the high-output characteristics and gain characteristics of the transistor. The greater the thickness of the in-situ Si₃N₄ film, the more the carrier concentration increases, resulting in higher saturation current, which enables increased high-output characteristics and gain characteristics of the transistor.

However, when the thickness of the in-situ Si₃N₄ film is large, wafer bow becomes a problem. FIG. 3 illustrates the relationship between the thickness of the Si₃N₄ film and wafer bow. In FIG. 3, the horizontal axis represents the thickness of the Si₃N₄ film, and the vertical axis represents wafer bow. Note that FIG. 3 illustrates measurement results for a 6-inch wafer.

As illustrated in FIG. 3, both the in-situ Si₃N₄ film and the ex-situ Si₃N₄ film tend to increase wafer bow as thickness increases. When wafer bow increases, problems arise such as the formation of cracks along the peripheral portion of the wafer, leading to degradation in the quality of semiconductor device 1. It is therefore necessary to establish an upper limit (critical thickness) for the thickness of the Si₃N₄ film provided on nitride semiconductor layer 104. For example, in the case of a 6-inch wafer, as illustrated in FIG. 3, the thickness at which wafer bow reaches 15 μm is considered the critical thickness. In such cases, the critical thickness of in-situ Si₃N₄ film is 25 nm.

When comparing at the same thickness, the amount of wafer bow when an in-situ Si₃N₄ film is provided is greater than the amount of wafer bow when an ex-situ Si₃N₄ film is provided. That is, from the perspective of inhibiting wafer bow, it is evident that the ex-situ Si₃N₄ film is more advantageous than the in-situ Si₃N₄ film.

Therefore, in the present embodiment, insulating layer 300 provided on nitride semiconductor layer 104 has a stacked structure of in-situ Si₃N₄ film 301 and ex-situ Si₃N₄ film 302. With this configuration, compared to when only in-situ Si₃N₄ film 301 is provided, the provision of ex-situ Si₃N₄ film 302 increases the piezo stress, enabling an increase in the electron carrier concentration of 2DEG 107. As a result, the saturation current of the transistor can be increased. This is because the saturation current depends on the electron carrier concentration rather than mobility, which has a greater influence at low voltages, since the saturation current is determined by the saturation velocity of electrons. As described above, in the present embodiment, it is possible to achieve both high drive current characteristics and low wafer bow characteristics.

As illustrated in FIG. 3, from the perspective of inhibiting the amount of wafer bow, there is also an upper limit (critical thickness) for the thickness of the ex-situ Si₃N₄ film. More specifically, the critical thickness of ex-situ Si₃N₄ film is 60 nm. In the present embodiment, since a stacked structure of in-situ Si₃N₄ film 301 and ex-situ Si₃N₄ film 302 is provided, when the thickness of in-situ Si₃N₄ film 301 is Tin and the thickness of ex-situ Si₃N₄ film 302 is Tex, the following Equation (1) is satisfied.

$$f ( {T}_{i n} ) + g ( {T}_{e x} ) \leq 15 μm \qquad ( 1 )$$

Note that f(Tᵢₙ) is a function representing the relationship between thickness Tᵢₙ of in-situ Si₃N₄ film 301 and wafer bow. g(Tₑₓ) is a function representing the relationship between thickness Tᵢₙ of ex-situ Si₃N₄ film 302 and wafer bow. Tᵢₙ is less than or equal to 25 nm, and Tₑₓ is less than or equal to 60 nm. By increasing Tᵢₙ and Tₑₓ within the constraints defined by Equation (1) to enhance piezo stress, it is possible to achieve both high drive current characteristics and low wafer bow characteristics.

As described above, in-situ Si₃N₄ film 301 is effective against collapse phenomena. The influence of the additionally stacked ex-situ Si₃N₄ film 302 on collapse phenomena will be explained below.

After stacking in-situ Si₃N₄ film 301 to a thickness that completely masks the epitaxial surface effects, subsequent deposition of ex-situ Si₃N₄ film 302, despite its many impurity levels, causes minimal collapse-related degradation. This is because ex-situ Si₃N₄ film 302, while having many impurity levels, also has characteristics that include high leakage current due to its film quality. Therefore, electrons trapped in the impurity levels are carried by the leakage current flowing through ex-situ Si₃N₄ film 302, creating a conduction mechanism where these electrons hop between these impurity levels. As a result, fewer electrons remain trapped in the impurity levels as fixed charges. It is therefore possible to inhibit the collapse phenomenon.

Also, in-situ Si₃N₄ film 301 has a certain number of impurity levels, though less than ex-situ Si₃N₄ film 302. Therefore, electrons may be trapped in the impurity levels of in-situ Si₃N₄ film 301. In contrast, in the present embodiment, electrons trapped in the impurity levels of in-situ Si₃N₄ film 301 can be conducted through the leakage path of ex-situ Si₃N₄ film 302 stacked on in-situ Si₃N₄ film 301. In this respect as well, forming a stacked structure is more effective for inhibiting collapse phenomena than providing in-situ Si₃N₄ film 301 alone, and can enhance drive current characteristics.

Note that when ex-situ Si₃N₄ film 302 is directly disposed on the epi surface, the leakage current becomes a non-negligible large amount. Therefore, by providing in-situ Si₃N₄ film 301 to cover the epi surface and providing ex-situ Si₃N₄ film 302 on in-situ Si₃N₄ film 301, it is possible to achieve both high drive current characteristics and low wafer bow characteristics.

Having the stacked structure of in-situ Si₃N₄ film 301 and ex-situ Si₃N₄ film 302 makes it possible to increase the distance between drain-side protruding portion 203d of gate electrode 203 and 2DEG 107. As a result, it is possible to reduce gate-drain capacitance Cgd, thereby making it possible to improve the gain.

### Embodiment 2

Next, Embodiment 2 will be described. In Embodiment 2, the main difference from Embodiment 1 is that a SiO₂ film is provided on the ex-situ Si₃N₄ film. The description below will focus on the differences from Embodiment 1, and the description of common points will be omitted or simplified.

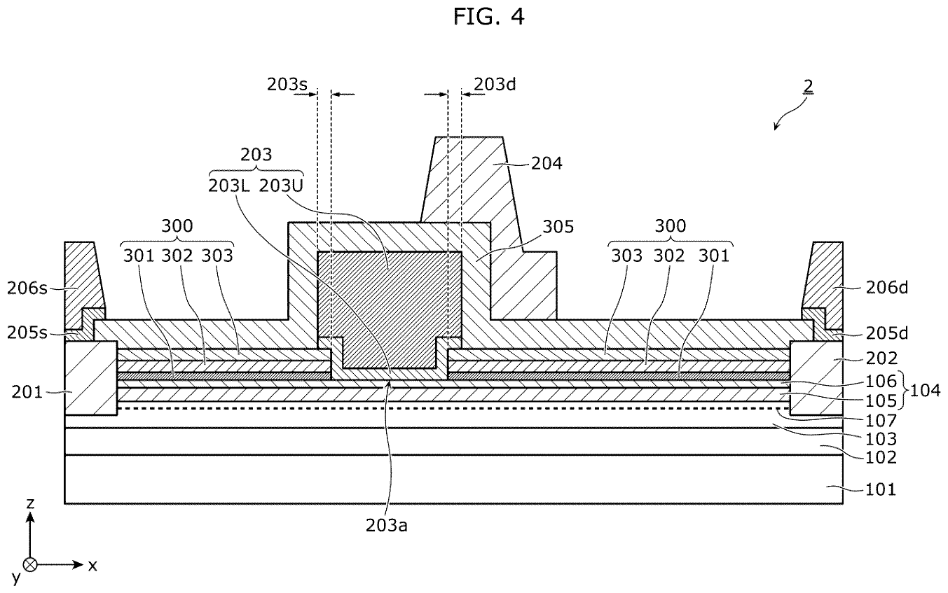

FIG. 4 is a cross-sectional view of semiconductor device 2 according to the present embodiment. As illustrated in FIG. 4, semiconductor device 2 differs from semiconductor device 1 illustrated in FIG. 1 in that insulating layer 300 further includes SiO₂ film 303.

SiO₂ film 303 is an example of a third insulating film consisting of silicon oxide that is positioned between drain-side protruding portion 203d and ex-situ Si₃N₄ film 302. SiO₂ film 303 is the uppermost layer in the stacked structure of insulating layer 300. SiO₂ film 303 is in contact with drain-side protruding portion 203d. More specifically, SiO₂ film 303 overlaps with drain-side protruding portion 203d in a plan view, and contacts the bottom surface of drain-side protruding portion 203d. In the present embodiment, between gate electrode 203 and drain electrode 202, SiO₂ film 303 is contacting and covering ex-situ Si₃N₄ film 302 over the entire area from the drain-side end portion of junction portion 203a to drain electrode 202.

In the present embodiment, SiO₂ film 303 is also disposed between gate electrode 203 and source electrode 201. More specifically, SiO₂ film 303 overlaps with source-side protruding portion 203s in a plan view, and contacts the bottom surface of source-side protruding portion 203s. SiO₂ film 303 is contacting and covering ex-situ Si₃N₄ film 302 over the entire area from the source-side end portion of junction portion 203a to source electrode 201.

The thickness of SiO₂ film 303 is, for example, greater than or equal to 10 nm and less than or equal to 100 nm, and in one example is 50 nm. In the present embodiment, the thickness of SiO₂ film 303 is substantially uniform.

While the relative dielectric constant of Si₃N₄ is approximately 7, the relative dielectric constant of SiO₂ is approximately 4. That is, SiO₂ film 303 has a lower dielectric constant than either in-situ Si₃N₄ film 301 or ex-situ Si₃N₄ film 302. Therefore, by providing SiO₂ film 303 between drain-side protruding portion 203d and 2DEG 107, gate-drain capacitance Cgd can be reduced. By reducing gate-drain capacitance Cgd, it is possible to improve high-frequency gain characteristics and efficiency performance of the transistor.

### Embodiment 3

Next, Embodiment 3 will be described. In Embodiment 2, the main difference from Embodiment 1 is that sidewall structures are provided in the gate portion. The description below will focus on the differences from Embodiment 1, and the description of common points will be omitted or simplified.

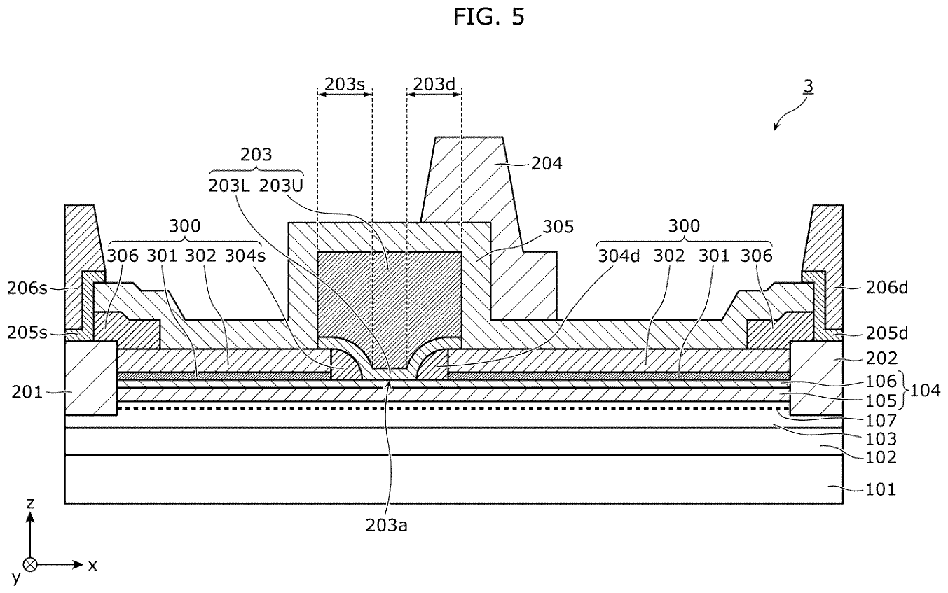

FIG. 5 is a cross-sectional view of semiconductor device 3 according to the present embodiment. As illustrated in FIG. 5, semiconductor device 3 differs from semiconductor device 1 illustrated in FIG. 1 in that insulating layer 300 further includes sidewalls 304d and 304s, and ex-situ Si₃N₄ film 306.

Sidewall 304d is disposed between junction portion 203a of gate electrode 203 and in-situ Si₃N₄ film 301. More specifically, sidewall 304d is a drain-side sidewall, and is disposed between junction portion 203a and the portion of in-situ Si₃N₄ film 301 on the drain electrode 202 side.

Sidewall 304s is disposed between junction portion 203a of gate electrode 203 and in-situ Si₃N₄ film 301. More specifically, sidewall 304s is a source-side sidewall, and is disposed between junction portion 203a and the portion of in-situ Si₃N₄ film 301 on the source electrode 201 side.

Sidewalls 304d and 304s both consist of silicon nitride. More specifically, sidewalls 304d and 304s consist of ex-situ Si₃N₄ and are formed in the same process.

The film quality of each of sidewalls 304d and 304s is different from the film quality of ex-situ Si₃N₄ film 302. More specifically, sidewalls 304d and 304s are films that are less dense than ex-situ Si₃N₄ film 302. For example, the film density of each of sidewalls 304d and 304s is less than the film density of ex-situ Si₃N₄ film 302. Sidewalls 304d and 304s are formed in a different process from ex-situ Si₃N₄ film 302. The specific formation method will be explained later.

Ex-situ Si₃N₄ film 306 is disposed above ex-situ Si₃N₄ film 302. More specifically, ex-situ Si₃N₄ film 306 is disposed at a position that does not overlap with drain-side protruding portion 203d of gate electrode 203 in a plan view. More specifically, ex-situ Si₃N₄ film 306 is disposed so as to be in contact with drain electrode 202.

Ex-situ Si₃N₄ film 306 is also disposed on the source electrode 201 side. More specifically, ex-situ Si₃N₄ film 306 is disposed at a position that does not overlap with source-side protruding portion 203s of gate electrode 203. More specifically, ex-situ Si₃N₄ film 306 is disposed so as to be in contact with source electrode 201.

The film quality of ex-situ Si₃N₄ film 306 is different from the film quality of ex-situ Si₃N₄ film 302. More specifically, ex-situ Si₃N₄ film 306 is a film that is less dense than ex-situ Si₃N₄ film 302. For example, the film density of ex-situ Si₃N₄ film 306 is less than the film density of ex-situ Si₃N₄ film 302. Ex-situ Si₃N₄ film 306 can be formed in the same process as sidewalls 304d and 304s.

By providing ex-situ Si₃N₄ film 306, insulating layer 300 has a greater thickness in the vicinity of drain electrode 202 than in the vicinity of gate electrode 203. In the direction directly below the portion with increased thickness, that is, in the direction directly below ex-situ Si₃N₄ film 306, more charge is generated due to piezoelectric polarization. Therefore, in the direction directly below ex-situ Si₃N₄ film 306, the carrier concentration of 2DEG 107 increases. Since ex-situ Si₃N₄ film 306 is disposed so as to be in contact with drain electrode 202, the carrier concentration of the portion of 2DEG 107 that contacts drain electrode 202 increases. Accordingly, the contact resistance between drain electrode 202 and 2DEG 107 can be reduced. Therefore, since the on-resistance is reduced, it is possible to obtain high drive current characteristics.

Since ex-situ Si₃N₄ film 306 is disposed so as to be in contact with source electrode 201, the contact resistance between source electrode 201 and 2DEG 107 can be reduced. Therefore, since the on-resistance is reduced, it is possible to obtain high drive current characteristics.

Note that ex-situ Si₃N₄ film 306 may be formed in a different process from sidewalls 304d and 304s. The film quality of ex-situ Si₃N₄ film 306 may be the same as the film quality of ex-situ Si₃N₄ film 302. Alternatively, ex-situ Si₃N₄ film 306 may be a denser film than ex-situ Si₃N₄ film 302. Ex-situ Si₃N₄ film 306 need not necessarily be provided.

In the present embodiment, since sidewalls 304d and 304s are formed using ex-situ Si₃N₄, in-situ Si₃N₄ film 301 and sidewalls 304d and 304s differ in at least one of halogen concentration or interface oxygen concentration. For example, in the present embodiment, at least one of the following is satisfied: (a) the halogen concentration of in-situ Si₃N₄ film 301 is lower than the halogen concentration of sidewalls 304d and 304s; or (b) the interface oxygen concentration between in-situ Si₃N₄ film 301 and nitride semiconductor layer 104 is lower than the interface oxygen concentration between sidewalls 304d and 304s and nitride semiconductor layer 104. More specifically, at least one of the following is satisfied: (c) the halogen concentration of in-situ Si₃N₄ film 301 is less than 1×10¹⁸ atom/cm³, and the halogen concentration of sidewalls 304d and 304s is greater than 1×10¹⁸ atom/cm³; or (d) the interface oxygen concentration between in-situ Si₃N₄ film 301 and nitride semiconductor layer 104 is less than 1×10²⁰ atom/cm³, and the interface oxygen concentration between sidewalls 304d and 304s and nitride semiconductor layer 104 is greater than 1×10²⁰ atom/cm³. Also, the same relationship is satisfied between ex-situ Si₃N₄ film 306 and in-situ Si₃N₄ film 301.

In configurations where sidewalls 304d and 304s are not provided, a portion of in-situ Si₃N₄ film 301 and ex-situ Si₃N₄ film 302 is removed so that the width of the gate opening portion corresponds to gate length Lg. For this reason, it is not possible to achieve gate length Lg that is less than the minimum processing limit of the gate opening portion.

In contrast, in semiconductor device 3 according to the present embodiment, gate length Lg can be shortened by providing sidewalls 304d and 304s. For example, it is possible to make gate length Lg less than or equal to 0.25 μm. Note that gate length Lg refers to the length of junction portion 203a along the arrangement direction (x-axis direction) of source electrode 201, gate electrode 203 (specifically, junction portion 203a), and drain electrode 202. For example, the length of each of sidewalls 304d and 304s in the x-axis direction can be 0.10 μm, and Lg can be 0.19 μm. That is, while the width of the gate opening portion is 0.39 μm, gate length Lg can be shortened to approximately half.

By shortening gate length Lg, a phenomenon called short channel effect may become a problem in the direction directly below gate electrode 203, where it becomes difficult to cut off (pinch off) the drive current when the device is off. In the present embodiment, since both sidewalls 304d and 304s are ex-situ Si₃N₄, they have weaker piezo stress compared to in-situ Si₃N₄. As a result, in 2DEG 107, the piezo charge in the direction directly below sidewalls 304d and 304s is reduced. As a result, the width of 2DEG 107 in the z-axis direction becomes narrower, so the current cutoff (pinch-off) characteristics during modulation of gate electrode 203 are improved.

### Embodiment 4

Next, Embodiment 4 will be described. In Embodiment 4, the main difference from Embodiment 3 is that a SiO₂ film is provided on the ex-situ Si₃N₄ film. In Embodiment 4, the main difference from Embodiment 2 is that sidewall structures are provided in the gate portion. The description below will focus on the differences from Embodiment 2 or 3, and the description of common points will be omitted or simplified.

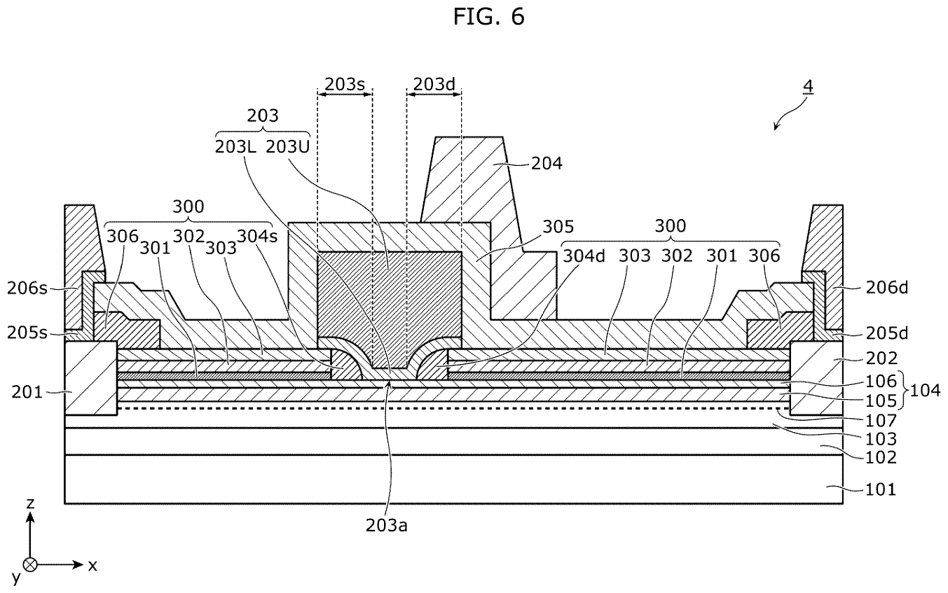

FIG. 6 is a cross-sectional view of semiconductor device 4 according to the present embodiment. As illustrated in FIG. 6, semiconductor device 4 differs from semiconductor device 3 illustrated in FIG. 5 in that insulating layer 300 further includes SiO₂ film 303.

SiO₂ film 303 is the same as SiO₂ film 303 included in insulating layer 300 of semiconductor device 2 according to Embodiment 2. Therefore, with semiconductor device 4 according to the present embodiment, it is possible to reduce gate-drain capacitance Cgd as with Embodiment 2, and it is possible to improve high-frequency gain characteristics and efficiency performance. More specifically, it is useful when handling signals in frequency bands of 5 GHz or higher.

Semiconductor device 4 according to the present embodiment includes sidewalls 304d and 304s consisting of ex-situ Si₃N₄, as in Embodiment 3. For this reason, the current cutoff (pinch-off) characteristics during modulation of gate electrode 203 are improved.

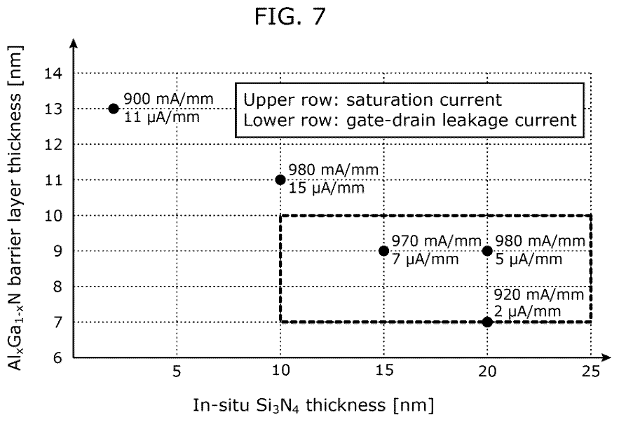

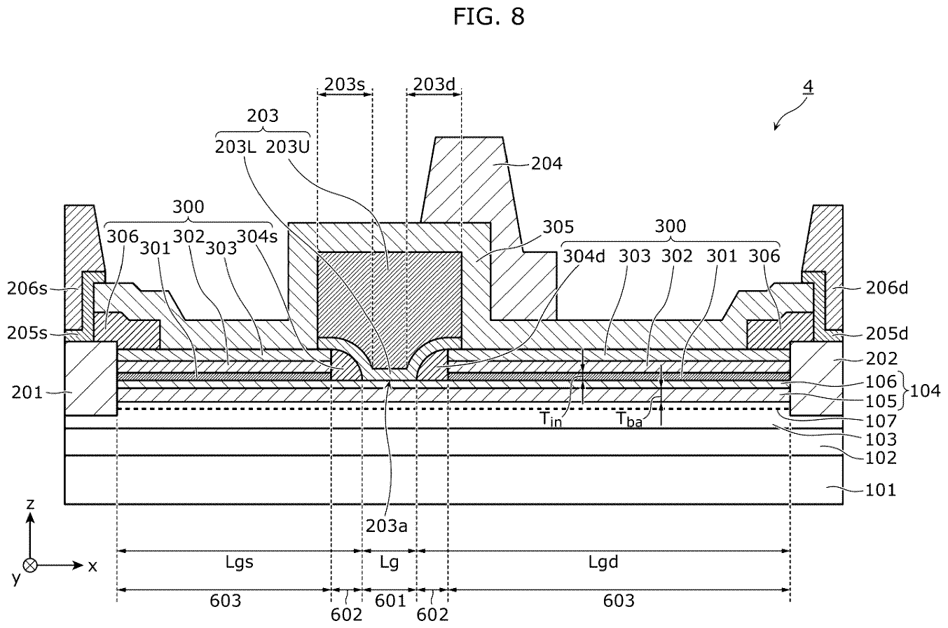

Next, actual data for a prototype of semiconductor device 4 according to the present embodiment will be described with reference to FIG. 7 and FIG. 8. FIG. 7 illustrates the current characteristics of semiconductor device 4 with respect to combinations of thickness Tᵢₙ of in-situ Si₃N₄ film 301 and thickness Tba of barrier layer 105. FIG. 8 is a cross-sectional view of semiconductor device 4 for supplementary explanation of the current characteristics illustrated in FIG. 7.

In FIG. 7, the numerical values shown alongside each plot represent the saturation current value in the upper row and the gate-drain leakage current value in the lower row. Table 2 below shows the data illustrated in FIG. 7.

TABLE 2

| | In-situ | | | |
|---|---|---|---|---|
| | Si₃N₄ | Barrier layer | Saturation | Leakage |
| | thickness | thickness T_{ba} | current | current |
| | Tᵢₙ[nm] | [nm] | [mA/mm] | [μA/mm] |
| Sample 1 | 2 | 13 | 900 | 11 |
| Sample 2 | 10 | 11 | 980 | 15 |
| Sample 3 | 15 | 9 | 970 | 7 |
| Sample 4 | 20 | 9 | 980 | 5 |
| Sample 5 | 20 | 7 | 920 | 2 |

Gate length Lg of each prototype (sample) was set to 0.25 μm. Barrier layer 105 is an AlₓGa₁₋ₓN film, and the composition ratio x of Al was set to 0.28. Saturation current is a value obtained by measuring the current flowing from drain electrode 202 to source electrode 201 when the drain voltage applied between drain electrode 202 and source electrode 201 is 5V. Leakage current is a value obtained by measuring the leakage current flowing from drain electrode 202 to gate electrode 203 when the electric potential difference between drain electrode 202 and gate electrode 203 is 150V. Distance Lgd between the gate and the drain was set to 3 μm. The longer Lgd is, the more the electric field concentration is mitigated, which reduces leakage current; however, this creates a problem where on-resistance increases.

When semiconductor device 4 is applied to a power amplifier, high saturation current and low leakage current are desired. Generally, if the saturation current is 920 mA/mm or greater, and the leakage current is 10 μA/mm or less, it is suitable for a power amplifier.

Depending on the conditions of thickness Tᵢₙ of in-situ Si₃N₄ film 301 and thickness Tba of barrier layer 105, it was possible to achieve both high saturation current and low leakage current, which were conventionally in a trade-off relationship. The following describes this mechanism with reference to FIG. 8 using Table 3. Note that Table 3 illustrates the characteristics of regions 601 to 603 illustrated in FIG. 8.

TABLE 3

| | Region 601 | | Region 603 |
|---|---|---|---|
| | Gate contact | Region 602 | Travel |
| | surface | Sidewall | region |
| Si₃N₄ | Schottky | Ex-situ Si₃N₄ | In-situ Si₃N₄/ |
| | junction | | Ex-situ Si₃N₄ |
| Barrier layer | Thinned | Thinned | Thinned |
| Leakage | Inhibited | — | — |
| current | | | |
| Drain current | Control region | High current | High current |
| | | Controllable | |
| | | inhibited region | |

First, we will focus on region 601. Region 601 is a region directly below junction portion 203a, which is the contact surface between gate electrode 203 and nitride semiconductor layer 104. In region 601, when barrier layer 105 is thinned, the piezo stress of barrier layer 105 with respect to channel layer 103 weakens. As a result, leakage current can also be inhibited. Stated differently, in the direction directly below junction portion 203a of gate electrode 203, thinning of barrier layer 105 is desirable.

However, in region 603, which is the main region where electron carriers travel between the gate and drain, barrier layer 105 is also thinned, so high saturation current cannot be expected as is. Therefore, in the present disclosure, in region 603, in-situ Si₃N₄ film 301 is stacked on thinned barrier layer 105. By utilizing the high piezo stress of in-situ Si₃N₄ film 301, the carrier concentration of 2DEG 107 can be increased, and the drain current can be increased.

As explained with reference to FIG. 2 and FIG. 3, since in-situ Si₃N₄ film 301 alone has a thickness limitation, ex-situ Si₃N₄ film 302 is additionally stacked. This makes it possible to achieve high saturation current while inhibiting wafer bow.

When sidewalls 304s and 304d are provided and gate length Lg is short, like in the present embodiment, a short channel effect occurs. More specifically, since a high drain current flows from drain electrode 202 side to region 601, it is difficult to block it with gate electrode 203. This is a phenomenon called punch-through due to short gate length.

Therefore, in semiconductor device 4 according to the present embodiment, ex-situ Si₃N₄ with weak stress is provided as sidewalls 304s and 304d in region 602. As a result, in region 602, the piezoelectric effect can be weakened, making it possible to block high drain current.

Thus, semiconductor device 4 of the present embodiment achieves a structure in which barrier layer 105, in-situ Si₃N₄ film 301, ex-situ Si₃N₄ film 302, and sidewalls 304s and 304d work together to complement each other's strengths and weaknesses. This configuration makes it possible to achieve both high saturation current and low leakage current, which were conventionally in a trade-off relationship, while also realizing low wafer bow characteristics. Stated differently, semiconductor device 4 according to the present embodiment makes it possible to provide a GaN HEMT having both high performance and high reliability with low leakage current. While semiconductor device 4 has been described as an example, the same applies to semiconductor devices 1 to 3 according to Embodiments 1 to 3.

Referring to FIG. 7 and Table 2, from the perspective of achieving saturation current of 920 mA/mm or greater, thickness Tᵢₙ of in-situ Si₃N₄ film 301 needs to be 7 nm or greater. From the perspective of wafer bow, thickness Tᵢₙ needs to be 25 nm or less. From the perspective of achieving leakage current of 10 μA/mm or less, thickness Tba of barrier layer 105 needs to be 10 nm or less. Based on the above, thickness Tᵢₙ of in-situ Si₃N₄ film 301 is in a range of 10 nm or greater and 25 nm or less, and thickness Tba of barrier layer 105 is 10 nm or less, thereby achieving both high saturation current and low leakage current while realizing low wafer bow characteristics. Note that depending on the lower limit of drive current and the upper limit of low leakage current required for the semiconductor device, thickness Tᵢₙ of in-situ Si₃N₄ film 301 may be less than 10 nm, or may be greater than 25 nm. Thickness Tba of barrier layer 105 may be greater than 10 nm, and may be less than 7 nm.

### (Manufacturing Method)

Next, a manufacturing method of semiconductor devices 1 to 4 according to the above-described Embodiments 1 to 4 will be described.

The manufacturing method of semiconductor devices 1 to 4 includes: a first process of sequentially forming, above substrate 101 by epitaxial growth, channel layer 103 and nitride semiconductor layer 104 that includes barrier layer 105; a second process of forming insulating layer 300 to cover nitride semiconductor layer 104; a third process of exposing a portion of nitride semiconductor layer 104 by removing a portion of insulating layer 300; a fourth process of forming source electrode 201 and drain electrode 202 spaced apart from each other above substrate 101; and a fifth process of forming gate electrode 203 between source electrode 201 and drain electrode 202 so as to be spaced apart from each of them, gate electrode being formed to contact the exposed portion of nitride semiconductor layer 104 and cover a portion of insulating layer 300 located on the drain electrode 202 side relative to the exposed portion.

The second process includes: after the first process, a process of forming in-situ Si₃N₄ film 301 that contacts and covers nitride semiconductor layer 104, without exposure to the atmosphere; and after forming in-situ Si₃N₄ film 301 and exposure to the atmosphere, a process of forming ex-situ Si₃N₄ film 302 above in-situ Si₃N₄ film 301.

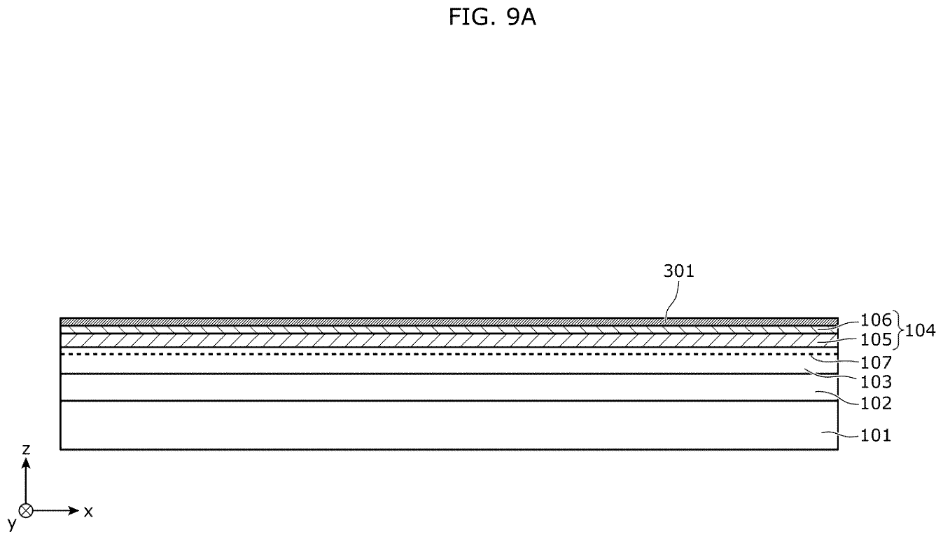

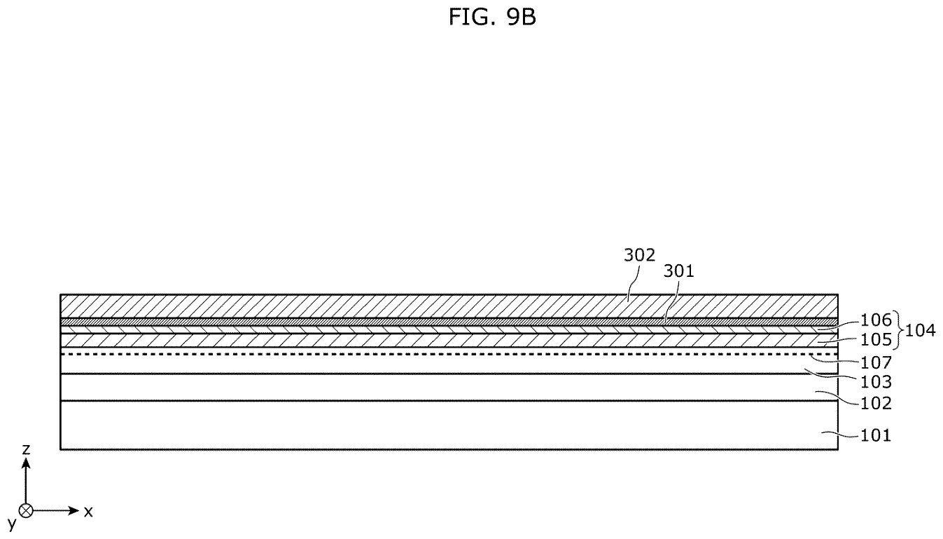

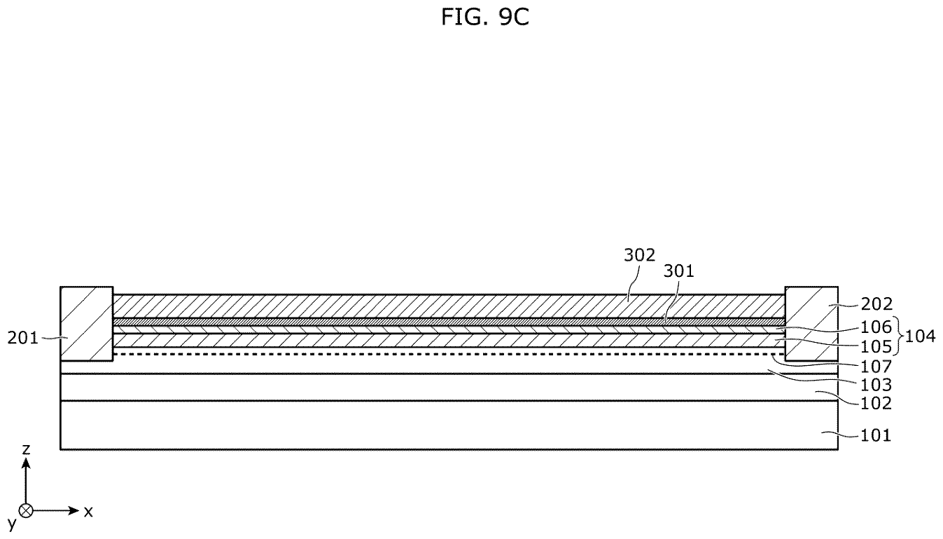

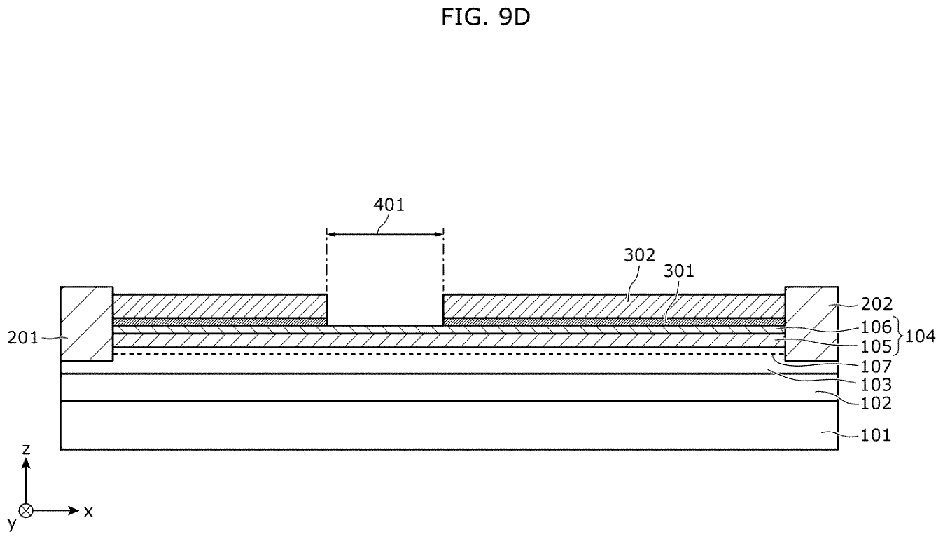

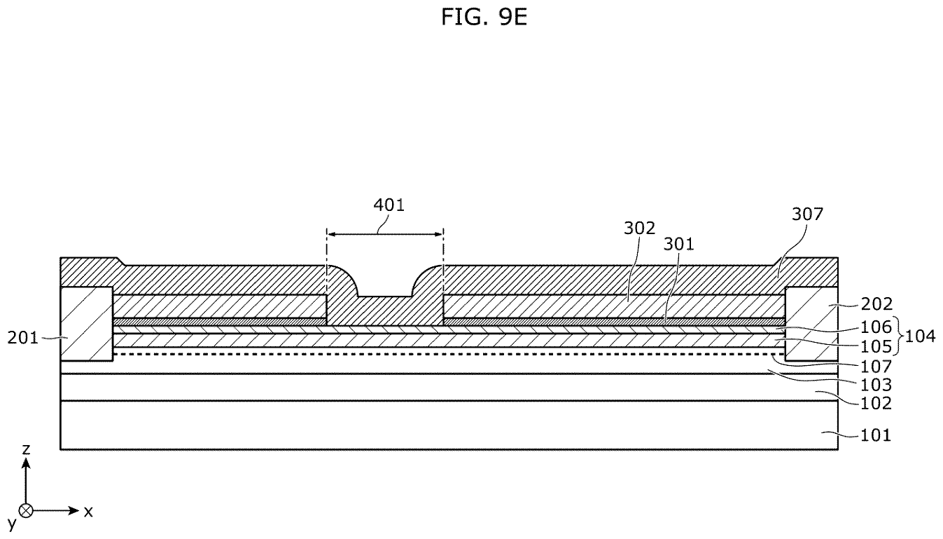

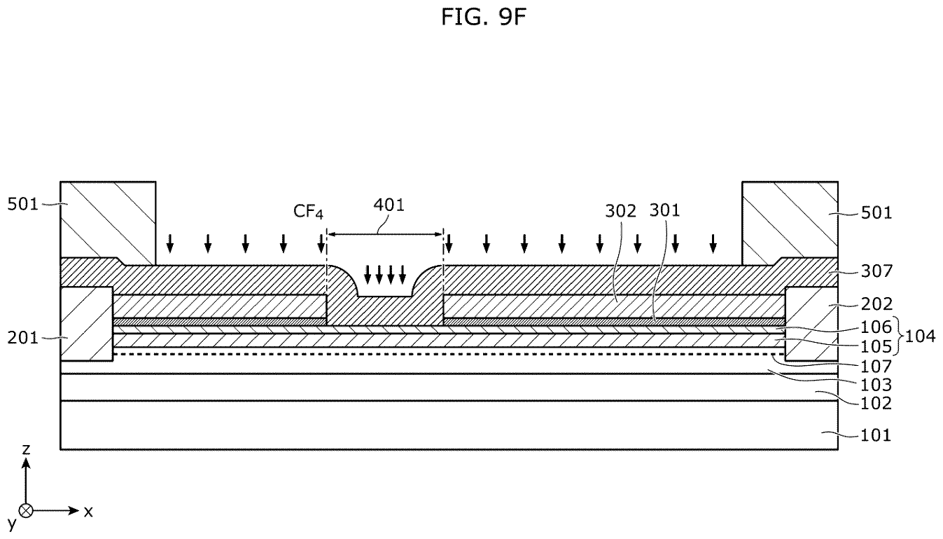

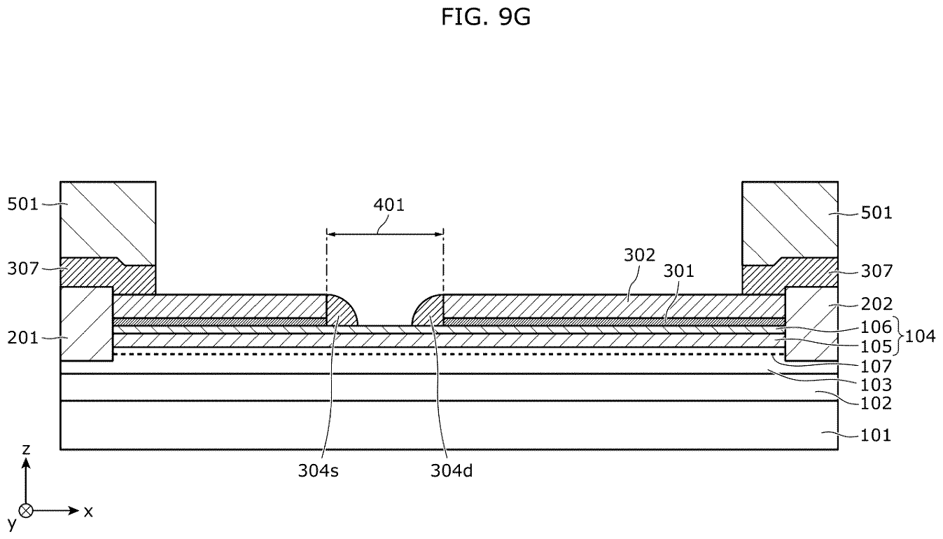

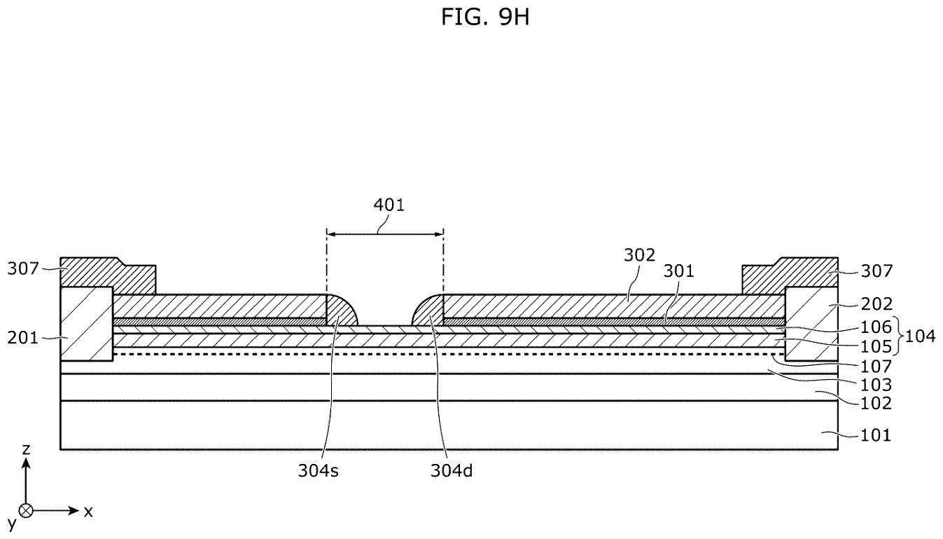

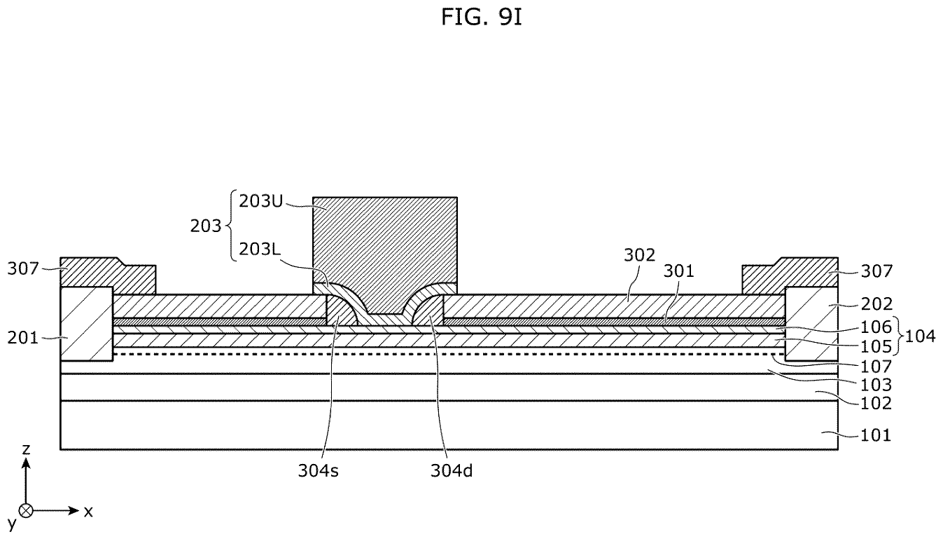

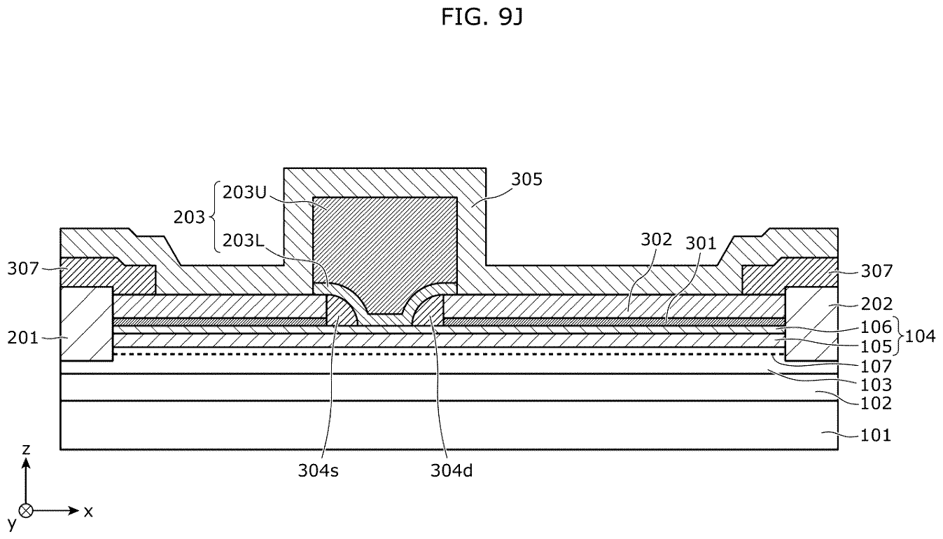

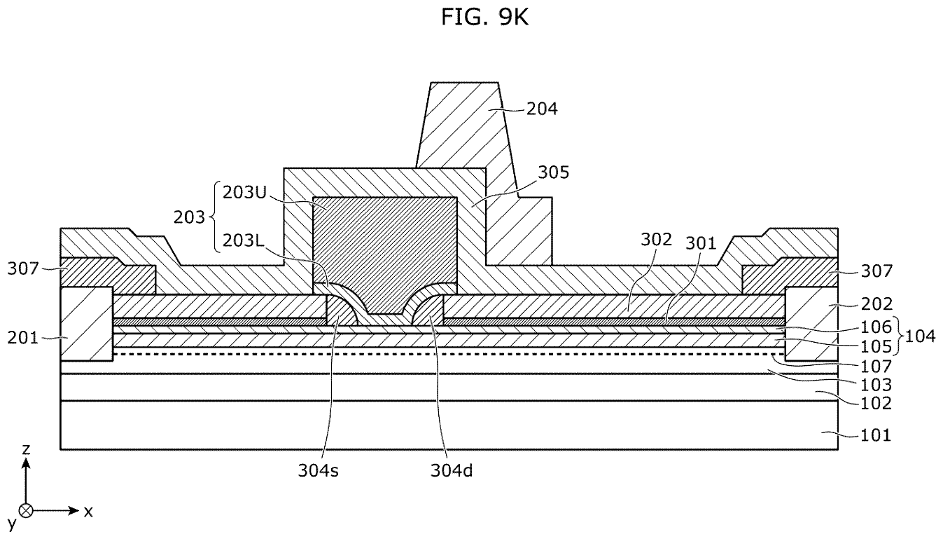

In the following, a manufacturing method of semiconductor device 3 according to Embodiment 3 will be described with reference to FIG. 9A to FIG. 9K. FIG. 9A to FIG. 9K are cross-sectional views for illustrating processes of the manufacturing method of semiconductor device 3 according to Embodiment 3.

The manufacturing method of semiconductor device 3 described below serves as the core for the manufacturing methods of each of semiconductor devices 1, 2, and 4 according to the other embodiments. The manufacturing methods of each of semiconductor devices 1, 2, and 4 can be easily implemented by merely omitting or modifying portions of the manufacturing method of semiconductor device 3 that will be described below.

First, as illustrated in FIG. 9A, a GaN wafer on which a nitride semiconductor has been epitaxially grown is prepared. More specifically, buffer layer 102, channel layer 103, barrier layer 105, and cap layer 106 are sequentially formed on substrate 101. For example, nitride semiconductors such as GaN, AlGaN, etc., are epitaxially grown in sequence. The epitaxial growth is performed, for example, in a growth furnace based on the MOCVD method. Buffer layer 102, channel layer 103, barrier layer 105, and cap layer 106 can be formed by adjusting the type and flow rate of the introduced gases.

Furthermore, following the formation of cap layer 106, in-situ Si₃N₄ film 301 is formed. More specifically, after the epitaxial growth of the nitride semiconductor, silicon nitride is epitaxially grown in the same growth furnace without exposure to the atmosphere. As a result, it is possible to form in-situ Si₃N₄ film 301 covering the top surface of cap layer 106. Since the top surface of cap layer 106 (nitride semiconductor layer 104) is not exposed to the atmosphere, the oxygen concentration at the interface between in-situ Si₃N₄ film 301 and cap layer 106 becomes low. The halogen concentration in in-situ Si₃N₄ film 301 also becomes low.

Next, as illustrated in FIG. 9B, ex-situ Si₃N₄ film 302 is formed on in-situ Si₃N₄ film 301. More specifically, the GaN wafer with the formed in-situ Si₃N₄ film 301 is exposed to the atmosphere by removing the GaN wafer from the growth furnace. After cleaning the surface of GaN wafer following atmospheric exposure, that is, the top surface of in-situ Si₃N₄ film 301 with an acid such as hydrofluoric acid, ex-situ Si₃N₄ film 302 is formed. The formation of ex-situ Si₃N₄ film 302 is performed, for example, by Low Pressure Chemical Vapor Deposition (LPCVD).

The deposition temperature in the LPCVD is approximately 800° C. Accordingly, the film density of ex-situ Si₃N₄ film 302 formed by LPCVD is lower than the film density of in-situ Si₃N₄ film 301, but it is higher in density compared to a Si₃N₄ film formed by plasma CVD which deposits at a temperature of approximately 300° C. to 500° C. Therefore, ex-situ Si₃N₄ film 302 has an intermediate stress. Therefore, in-situ Si₃N₄ film 301 is more useful as a film for compensating piezo stress, particularly because it has a critical thickness determined by wafer bow. It goes without saying that ex-situ Si₃N₄ film 302 may be a Si₃N₄ film formed by conventional plasma CVD.

Next, although not illustrated in the figures, regions outside the transistor formation region (also called the active region) are deactivated by injecting ions that deactivate the nitride semiconductor, such as boron ions (B⁺). This enables electrical isolation between devices within the GaN wafer.

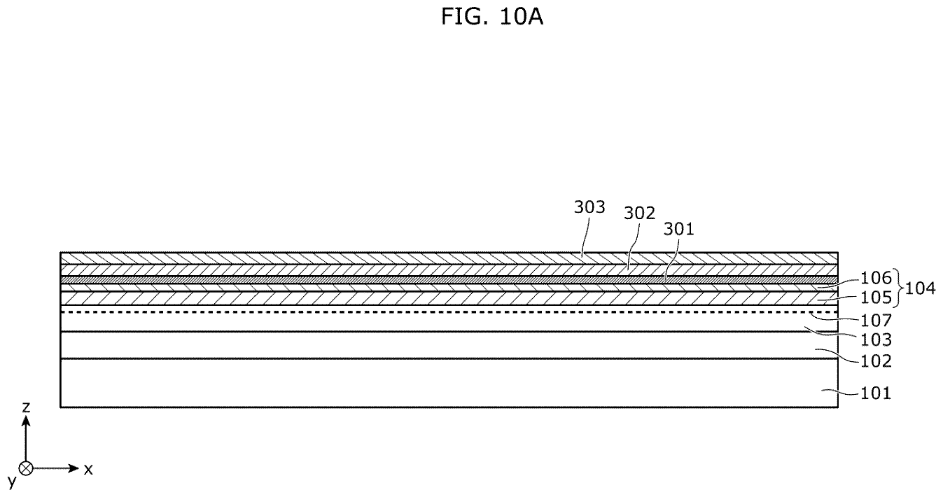

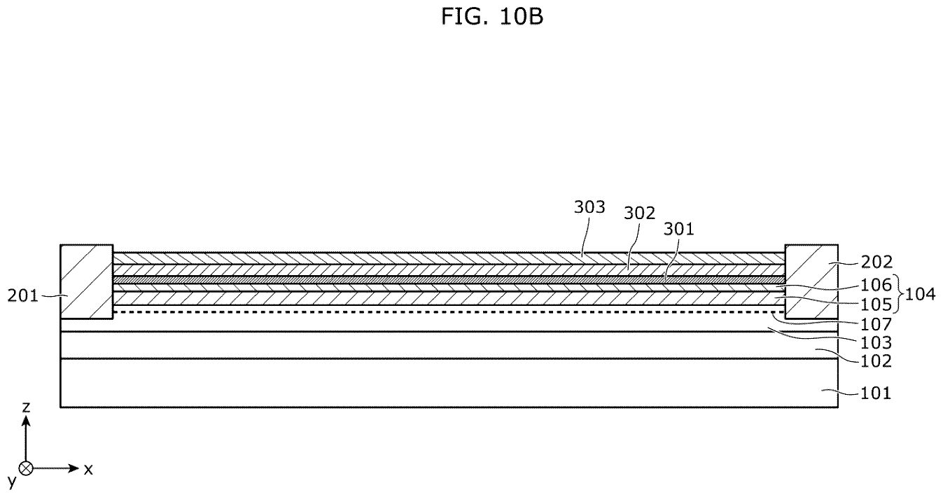

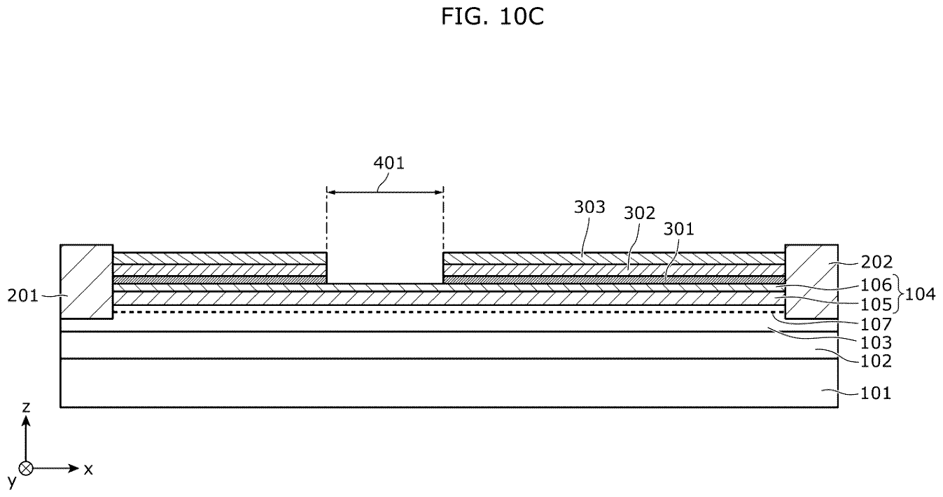

Next, source electrode 201 and drain electrode 202 are formed as illustrated in FIG. 9C. Note that FIG. 9C through FIG. 9K illustrate only one transistor formation region within the GaN wafer. In each figure, the non-illustrated portions to the left of source electrode 201 (negative side of the x-axis) and to the right of drain electrode 202 (positive side of the x-axis) are electrical isolation regions. The same applies to FIG. 10B and FIG. 10C to be described later.

In the process of forming source electrode 201 and drain electrode 202, first, opening portions (contact holes) are formed by removing portions of ex-situ Si₃N₄ film 302 and in-situ Si₃N₄ film 301 through etching. Furthermore, continuously from the formation of the contact holes, a recessed portion is formed by removing cap layer 106, barrier layer 105, and channel layer 103 through etching until 2DEG 107 is exposed. The etching is performed, for example, by dry etching. After depositing a metal film by sputtering or vapor deposition to cover the inner surface of the formed recessed portion, source electrode 201 and drain electrode 202 are formed by patterning the metal film. Note that the patterning is performed, for example, by etching or lift-off. Subsequently, by alloying the semiconductor and metal at a temperature of approximately 500° C. to 600° C., each of source electrode 201 and drain electrode 202 is made to have ohmic contact with channel layer 103.

Next, as illustrated in FIG. 9D, a gate opening portion is formed in gate region 401 for forming a gate. The length of gate region 401 in the x-axis direction is, for example, 0.39 μm. More specifically, a positive photoresist is applied on ex-situ Si₃N₄ film 302, and gate region 401 of the applied photoresist is opened. Dry etching with plasma ions containing CF₄ removes the exposed portions of ex-situ Si₃N₄ film 302 and in-situ Si₃N₄ film 301 in gate region 401.

Next, as illustrated in FIG. 9E, ex-situ Si₃N₄ film 307 is formed on the entire surface, including the opening portion of gate region 401. Ex-situ Si₃N₄ film 307 is formed by, for example, plasma CVD, but may be formed by LPCVD. Ex-situ Si₃N₄ film 307 is a silicon nitride film that serves as the base for sidewalls 304s and 304d, as well as ex-situ Si₃N₄ film 306. Specifically, ex-situ Si₃N₄ film 307 is deposited with the same thickness as the total thickness of in-situ Si₃N₄ film 301 and ex-situ Si₃N₄ film 302. For example, when the thickness of in-situ Si₃N₄ film 301 is 20 nm and the thickness of ex-situ Si₃N₄ film 302 is 30 nm, the thickness of ex-situ Si₃N₄ film 307 is set to 50 nm. By matching thicknesses, the height of sidewalls 304s and 304d can be aligned with the height (total thickness) of in-situ Si₃N₄ film 301 and ex-situ Si₃N₄ film 302.

Next, as illustrated in FIG. 9F, after forming photoresist 501 having an opening portion of a predetermined shape, anisotropic dry etching is performed using plasma ions mainly containing CF₄ to remove ex-situ Si₃N₄ film 307 exposed in the opening portions of photoresist 501. Photoresist 501 has a shape that covers source electrode 201 and drain electrode 202, and does not cover at least gate region 401. The etching amount is the thickness of the deposited ex-situ Si₃N₄ film 307, for example, 50 nm. Photoresist 501 is a positive type, but may be a negative type.

As a result of the anisotropic etching, sidewall 304s and sidewall 304d are formed, as illustrated in FIG. 9G. Sidewall 304s and sidewall 304d are the remaining portions of ex-situ Si₃N₄ film 307 that were not removed along the opening wall in gate region 401.

Due to the anisotropic etching process used on ex-situ Si₃N₄ film 307, the top surfaces of sidewalls 304s and 304d replicate the shape of the top surface of ex-situ Si₃N₄ film 307. This shape is generally referred to as a sidewall shape. Due to the formation of sidewalls 304s and 304d in gate region 401, the length of the exposed portion of nitride semiconductor layer 104 in gate region 401 (i.e., gate length Lg) is reduced. More specifically, gate length Lg is reduced from 0.39 μm to 0.19 μm.

When the length of gate region 401 is 0.4 μm, it is possible to form the gate opening portion using i-line photolithography, which is a conventional optical exposure technique. However, it is difficult to form the gate opening portion with a length of 0.25 μm or less. Thus, by forming sidewalls 304s and 304d, gate length Lg can be easily reduced.

Furthermore, as illustrated in FIG. 9H, photoresist 501 is removed using an organic solvent such as acetone. As a result, a portion of ex-situ Si₃N₄ film 307 remains on parts covering source electrode 201 and drain electrode 202.

Next, gate electrode 203 is formed as illustrated in FIG. 9I. More specifically, a first conductive film made of a material that forms a Schottky junction with the nitride semiconductor is formed as gate electrode lower portion 203L, and a second conductive film made of a material having a lower resistivity than the first conductive film is formed as gate electrode upper portion 203U. For example, after continuously forming the first conductive film and the second conductive film over the entire surface by sputtering or the like, a resist mask may be formed and unnecessary portions may be removed by dry etching. Alternatively, gate electrode 203 may be formed by lift-off method. More specifically, after forming a resist film having an opening in a portion corresponding to gate electrode 203, the first conductive film and the second conductive film may be continuously deposited, and the resist film may be removed together with the first conductive film and the second conductive film provided on the resist film.

It should be noted that the thicker the thickness of gate electrode upper portion 203U, the greater the reduction in gate resistance Rg that can be expected. However, due to the skin effect of metal, current flows only through the surface (skin portion) in the case of high frequency. It is therefore not necessarily better for gate electrode upper portion 203U to be thicker. In the case of gate electrode upper portion 203U consisting of Al, a thickness of approximately 450 nm is sufficient to accommodate the frequency bands currently applied. Thickening of gate electrode upper portion 203U may be subject to constraints such as deposition time and etching time, as well as the thickness of the photoresist mask. For example, when depositing Al by sputtering, the greater the thickness, the longer the deposition time and etching time become, which may cause the resist mask for processing to become baked and difficult to remove. When depositing by evaporation lift-off method, poor lift-off characteristics can easily cause shape abnormalities. For this reason, gate electrode upper portion 203U is set to a maximum thickness of approximately 650 nm.

Next, as illustrated in FIG. 9J, insulating layer 305 is formed to protect gate electrode 203. As insulating layer 305, an ex-situ Si₃N₄ film is formed by, for example, plasma CVD or LPCVD.

Next, source field plate 204 is formed as illustrated in FIG. 9K. Source field plate 204 is formed by depositing a metal film by sputtering and removing by dry etching. Alternatively, source field plate 204 may be formed by vapor deposition lift-off. When Au is used, vapor deposition lift-off is employed because dry etching cannot be performed.

Next, in order to ensure electrical connection with source electrode 201 and drain electrode 202, opening portions are first formed in insulating layer 305 and ex-situ Si₃N₄ film 307. The formation of the opening portions is performed by forming a photoresist having opening portions provided to expose source electrode 201 and drain electrode 202, and then dry etching with plasma ions containing CF₄. Ex-situ Si₃N₄ film 307 having opening portions provided for contact to each of source electrode 201 and drain electrode 202 becomes ex-situ Si₃N₄ film 306 illustrated in FIG. 5. Subsequently, barrier metals 205s and 205d and wiring metals 206s and 206d of predetermined shapes are formed to cover the opening portions. Barrier metals 205s and 205d, as well as wiring metals 206s and 206d, are formed by sputtering and dry etching, or by deposition lift-off method.

Through the above processes, semiconductor device 3 illustrated in FIG. 5 can be manufactured.

Note that when manufacturing semiconductor device 1 illustrated in FIG. 1, the process of forming sidewalls 304s and 304d may be omitted. More specifically, the processes described with reference to FIG. 9E through FIG. 9H may be omitted. After forming gate region 401 as illustrated in FIG. 9D, gate electrode 203 may be formed as illustrated in FIG. 9J.

Semiconductor device 2 or 4 according to Embodiment 2 or 4 can also be manufactured through processes substantially similar to the manufacturing method of semiconductor device 3. The following describes the differences between the manufacturing method of semiconductor device 3 and the manufacturing method of semiconductor device 4, with reference to FIG. 10A through FIG. 10C. FIG. 10A to FIG. 10C are cross-sectional views for illustrating processes of the manufacturing method of semiconductor device 4 according to Embodiment 4.

In the manufacturing method of semiconductor device 4, the processes up to forming the in-situ Si₃N₄ film 301 are the same as the manufacturing method of semiconductor device 3, as described with reference to FIG. 9A. As illustrated in FIG. 10A, ex-situ Si₃N₄ film 302 and SiO₂ film 303 are formed on in-situ Si₃N₄ film 301. More specifically, the GaN wafer with the formed in-situ Si₃N₄ film 301 is exposed to the atmosphere by removing the GaN wafer from the growth furnace. After cleaning the surface of GaN wafer following atmospheric exposure, that is, the top surface of in-situ Si₃N₄ film 301 with an acid such as hydrofluoric acid, ex-situ Si₃N₄ film 302 and SiO₂ film 303 are continuously formed. The formation of ex-situ Si₃N₄ film 302 and SiO₂ film 303 is performed, for example, by plasma CVD. Alternatively, ex-situ Si₃N₄ film 302 may be formed by LPCVD, and SiO₂ film 303 may be formed by plasma CVD.

Next, source electrode 201 and drain electrode 202 are formed as illustrated in FIG. 10B. It should be noted that before the formation of source electrode 201 and drain electrode 202, a process is performed to deactivate regions other than the transistor formation region.

In the process of forming source electrode 201 and drain electrode 202, the difference is that not only ex-situ Si₃N₄ film 302 and in-situ Si₃N₄ film 301, but also a portion of SiO₂ film 303 is removed to form contact holes. The formation and patterning of the metal film, as well as processes such as alloying, are the same as in the manufacturing method of semiconductor device 3.

Next, as illustrated in FIG. 10C, a gate opening portion is formed in gate region 401 for forming a gate. In the formation of the gate opening portion, the difference is that not only ex-situ Si₃N₄ film 302 and in-situ Si₃N₄ film 301, but also a portion of SiO₂ film 303 is removed. The removal of SiO₂ film 303 is performed, for example, by dry etching using CF₄ gas.

The subsequent processes are the same as in the manufacturing method of semiconductor device 3. More specifically, each process described with reference to FIG. 9E through FIG. 9K is performed.

When manufacturing semiconductor device 2 illustrated in FIG. 4, the process of forming sidewalls 304s and 304d may be omitted. More specifically, the processes described with reference to FIG. 9E through FIG. 9H may be omitted. After forming gate region 401 as illustrated in FIG. 10C, gate electrode 203 may be formed as illustrated in FIG. 9J.

### Summary

Hereinafter, features of the semiconductor device explained based on the above embodiments will be described.

A semiconductor device according to a first aspect of the present disclosure includes: a substrate; a channel layer disposed above the substrate and including a nitride semiconductor containing gallium; a nitride semiconductor layer disposed above the channel layer and including a barrier layer containing gallium with a bandgap larger than a bandgap of the channel layer; a source electrode and a drain electrode disposed above the substrate and spaced apart from each other; a gate electrode disposed above the barrier layer and between the source electrode and the drain electrode, and spaced apart from each of the source electrode and the drain electrode; and an insulating layer disposed above the nitride semiconductor layer and between the gate electrode and the drain electrode. The gate electrode includes: a junction portion that forms a Schottky junction with the nitride semiconductor layer; and a first protruding portion that protrudes toward the drain electrode from the junction portion. The insulating layer includes: a first insulating film including silicon nitride, positioned between the first protruding portion and the nitride semiconductor layer, and contacting and covering the nitride semiconductor layer; and a second insulating film including silicon nitride and positioned between the first protruding portion and the first insulating film. The semiconductor device satisfies at least one of: (a) a halogen concentration of the first insulating film is lower than a halogen concentration of the second insulating film; or (b) an interface oxygen concentration between the first insulating film and the nitride semiconductor layer is lower than an interface oxygen concentration between the second insulating film and the first insulating film.

As a result, since a stacked structure of the first insulating film and the second insulating film is provided, it is possible to achieve a semiconductor device having both high drive current characteristics and low wafer bow characteristics.

The semiconductor device according to a second aspect of the present disclosure is the semiconductor device according to the first aspect, wherein the semiconductor device satisfies at least one of: (c) the halogen concentration of the first insulating film is less than 1×10¹⁸ atom/cm³ and the halogen concentration of the second insulating film is greater than 1×10¹⁸ atom/cm³; or (d) the interface oxygen concentration between the first insulating film and the nitride semiconductor layer is less than 1×10²⁰ atom/cm³ and the interface oxygen concentration between the second insulating film and the first insulating film is greater than 1×10²⁰ atom/cm³.

As a result, since in-situ Si₃N₄ film is provided as the first insulating film and ex-situ Si₃N₄ film is provided as the second insulating film, it is possible to effectively utilize the high piezo stress of the in-situ Si₃N₄ film while also effectively utilizing the wafer bow inhibition effect of the ex-situ Si₃N₄ film. Moreover, it is possible to inhibit fixed charges from remaining by utilizing electron hopping in the lateral direction of the ex-situ Si₃N₄ film, thereby inhibiting current collapse. Therefore, with the present aspect, it is possible to achieve a semiconductor device having both high drive current characteristics and low wafer bow characteristics.

The semiconductor device according to a third aspect of the present disclosure is the semiconductor device according to the first aspect or the second aspect, wherein the insulating layer further includes a third insulating film including silicon oxide, positioned between the first protruding portion and the second insulating film, and contacting the first protruding portion.

With this configuration, gate-drain capacitance Cgd can be reduced by the third insulating film consisting of silicon oxide having a low dielectric constant. It is thus possible to improve high-frequency gain characteristics and efficiency performance of the transistor.

The semiconductor device according to a fourth aspect of the present disclosure is the semiconductor device according to any one of the first to third aspects, wherein a thickness of the first insulating film is greater than or equal to 10 nm, and a thickness of the barrier layer is greater than or equal to 7 nm.

This configuration makes it possible to achieve both high drive current and low leakage current.

The semiconductor device according to a fifth aspect of the present disclosure is the semiconductor device according to the fourth aspect, wherein the thickness of the barrier layer is less than or equal to 10 nm.

This configuration makes it possible to achieve both high drive current and low leakage current.

The semiconductor device according to a sixth aspect of the present disclosure is the semiconductor device according to the fourth aspect or the fifth aspect, wherein the thickness of the first insulating film is less than or equal to 25 nm.

This configuration makes it possible to achieve high drive current, low leakage current, and low wafer bow characteristics.

The semiconductor device according to a seventh aspect of the present disclosure is the semiconductor device according to any one of the first to sixth aspects, wherein the insulating layer further includes a sidewall including silicon nitride and provided between the junction portion and the first insulating film, and the semiconductor device satisfies at least one of: (e) the halogen concentration of the first insulating film is lower than a halogen concentration of the sidewall; or (f) the interface oxygen concentration between the first insulating film and the nitride semiconductor layer is lower than an interface oxygen concentration between the sidewall and the nitride semiconductor layer.

This configuration makes it possible to shorten the gate length. It is possible to reduce the carrier concentration of 2DEG in the direction directly below the sidewall, making it easier to control cutoff by the gate.

The semiconductor device according to an eighth aspect of the present disclosure is the semiconductor device according to the seventh aspect, wherein a film quality of the sidewall is different from a film quality of the second insulating film.

With this configuration, it is possible to reduce the carrier concentration of 2DEG in the direction directly below the sidewall, making it easier to control cutoff by the gate.

A manufacturing method of a semiconductor device according to a ninth aspect of the present disclosure includes: a first process of sequentially forming, above a substrate by epitaxial growth, a channel layer including a nitride semiconductor containing gallium and a nitride semiconductor layer including a barrier layer containing gallium with a bandgap larger than a bandgap of the channel layer; a second process of forming an insulating layer to cover the nitride semiconductor layer; a third process of exposing a portion of the nitride semiconductor layer by removing a portion of the insulating layer; a fourth process of forming a source electrode and a drain electrode spaced apart from each other above the substrate; and a fifth process of forming a gate electrode between the source electrode and the drain electrode so as to be spaced apart from each of the source electrode and the drain electrode, the gate electrode being formed to contact an exposed portion of the nitride semiconductor layer and cover a portion of the insulating layer located toward the drain electrode relative to the exposed portion. The second process includes: after the first process, a process of forming a first insulating film including silicon nitride that contacts and covers the nitride semiconductor layer, without exposure to an atmosphere; and after forming the first insulating film, a process of forming a second insulating film including silicon nitride above the first insulating film, after exposure to the atmosphere.

This configuration makes it possible to manufacture a semiconductor device having both high drive current characteristics and low wafer bow characteristics.

The manufacturing method of the semiconductor device according to a tenth aspect of the present disclosure is the manufacturing method of the semiconductor device according to the ninth aspect, wherein in the second process, the second insulating film is formed by Low Pressure Chemical Vapor Deposition (LPCVD).

By doing so, the piezo stress of the ex-situ Si₃N₄ film can also be increased, the carrier concentration of the 2DEG can be increased, and the drive current can be further increased.

### Other Embodiments

Although the semiconductor device and the manufacturing method thereof according to one or more aspects has been described above based on the embodiments, the present disclosure is not limited to the above-described embodiments. Various modifications to the present embodiment that may be conceived by those skilled in the art, as well as embodiments resulting from combinations of elements from different embodiments, are intended to be included within the scope of the present disclosure as long as these do not depart from the essence of the present disclosure.

For example, in each embodiment, insulating layer 300 need not necessarily be provided between source electrode 201 and gate electrode 203. Alternatively, in-situ Si₃N₄ film 301 may be provided between source electrode 201 and gate electrode 203, while ex-situ Si₃N₄ film 302 need not necessarily be provided.

Also, insulating layer 300 need not necessarily be provided in a portion between drain electrode 202 and gate electrode 203. More specifically, insulating layer 300 only needs to be provided at least in the region that overlaps with drain-side protruding portion 203d in plan view. Insulating layer 300 need not be disposed in the area from the drain-side end portion of drain-side protruding portion 203d to drain electrode 202 in plan view. Alternatively, in-situ Si₃N₄ film 301 may be provided in the area from the drain-side end portion of drain-side protruding portion 203d to drain electrode 202, while ex-situ Si₃N₄ film 302 need not necessarily be provided.

Although each of source electrode 201 and drain electrode 202 is formed to be embedded in barrier layer 105 and channel layer 103, the present disclosure is not limited to this. Source electrode 201 and drain electrode 202 may be provided on the top surface of barrier layer 105 or cap layer 106. That is, source electrode 201 and drain electrode 202 need not necessarily be in contact with 2DEG 107.

In addition, various changes, substitutions, additions, omissions, and so on, can be carried out in the above-described respective embodiments within the scope of the claims or its equivalents.

### INDUSTRIAL APPLICABILITY

The present disclosure is applicable in, for example, power amplifiers for high-output or high-frequency applications, wireless communication base stations or terminal devices in which such power amplifiers are used, or wireless power supply devices that transmit power using microwaves.

1. A semiconductor device comprising:
a substrate;
a channel layer disposed above the substrate and including a nitride semiconductor containing gallium;
a nitride semiconductor layer disposed above the channel layer and including a barrier layer containing gallium with a bandgap larger than a bandgap of the channel layer;
a source electrode and a drain electrode disposed above the substrate and spaced apart from each other;
a gate electrode disposed above the barrier layer and between the source electrode and the drain electrode, and spaced apart from each of the source electrode and the drain electrode; and
an insulating layer disposed above the nitride semiconductor layer and between the gate electrode and the drain electrode, wherein
the gate electrode includes:
a junction portion that forms a Schottky junction with the nitride semiconductor layer; and
a first protruding portion that protrudes toward the drain electrode from the junction portion,
the insulating layer includes:
a first insulating film including silicon nitride, positioned between the first protruding portion and the nitride semiconductor layer, and contacting and covering the nitride semiconductor layer; and
a second insulating film including silicon nitride and positioned between the first protruding portion and the first insulating film, and
the semiconductor device satisfies at least one of:
(a) a halogen concentration of the first insulating film is lower than a halogen concentration of the second insulating film; or
(b) an interface oxygen concentration between the first insulating film and the nitride semiconductor layer is lower than an interface oxygen concentration between the second insulating film and the first insulating film.

2. The semiconductor device according to claim 1, wherein
the semiconductor device satisfies at least one of:
(c) the halogen concentration of the first insulating film is less than 1×10¹⁸ atom/cm³ and the halogen concentration of the second insulating film is greater than 1×10¹⁸ atom/cm³; or
(d) the interface oxygen concentration between the first insulating film and the nitride semiconductor layer is less than 1×10²⁰ atom/cm³ and the interface oxygen concentration between the second insulating film and the first insulating film is greater than 1×10²⁰ atom/cm³.

3. The semiconductor device according to claim 1, wherein
the insulating layer further includes a third insulating film including silicon oxide, positioned between the first protruding portion and the second insulating film, and contacting the first protruding portion.

4. The semiconductor device according to claim 1, wherein
a thickness of the first insulating film is greater than or equal to 10 nm, and
a thickness of the barrier layer is greater than or equal to 7 nm.

5. The semiconductor device according to claim 4, wherein
the thickness of the barrier layer is less than or equal to 10 nm.

6. The semiconductor device according to claim 4, wherein
the thickness of the first insulating film is less than or equal to 25 nm.

7. The semiconductor device according to claim 1, wherein
the insulating layer further includes a sidewall including silicon nitride and provided between the junction portion and the first insulating film, and
the semiconductor device satisfies at least one of:
(e) the halogen concentration of the first insulating film is lower than a halogen concentration of the sidewall; or
(f) the interface oxygen concentration between the first insulating film and the nitride semiconductor layer is lower than an interface oxygen concentration between the sidewall and the nitride semiconductor layer.

8. The semiconductor device according to claim 7, wherein
a film quality of the sidewall is different from a film quality of the second insulating film.

9. A manufacturing method of a semiconductor device, the manufacturing method comprising:
a first process of sequentially forming, above a substrate by epitaxial growth, a channel layer including a nitride semiconductor containing gallium and a nitride semiconductor layer including a barrier layer containing gallium with a bandgap larger than a bandgap of the channel layer;
a second process of forming an insulating layer to cover the nitride semiconductor layer;
a third process of exposing a portion of the nitride semiconductor layer by removing a portion of the insulating layer;
a fourth process of forming a source electrode and a drain electrode spaced apart from each other above the substrate; and
a fifth process of forming a gate electrode between the source electrode and the drain electrode so as to be spaced apart from each of the source electrode and the drain electrode, the gate electrode being formed to contact an exposed portion of the nitride semiconductor layer and cover a portion of the insulating layer located toward the drain electrode relative to the exposed portion, wherein
the second process includes:
after the first process, a process of forming a first insulating film including silicon nitride that contacts and covers the nitride semiconductor layer, without exposure to an atmosphere; and
after forming the first insulating film, a process of forming a second insulating film including silicon nitride above the first insulating film, after exposure to the atmosphere.

10. The manufacturing method of the semiconductor device according to claim 9, wherein
in the second process, the second insulating film is formed by Low Pressure Chemical Vapor Deposition (LPCVD).
